(19) United States
(12) Patent Application Publication
(10) Pub. No.: US 2026/0101507 A1
(43) Pub. Date: Apr. 9, 2026

(54) METHOD OF INTEGRATION OF NON-VOLATILE MEMORY DEVICE HAVING VERTICAL CHANNELS FORMATION INTO CMOS FLOW

(71) Applicant: Infineon Technologies LLC, San Jose, CA (US)

(72) Inventors: Yanli ZHANG, San Jose, CA (US); Shivananda Shetty, Fremont, CA (US); James Pak, Sunnyvale, CA (US); Hidehiko SHIRAIWA, Battle Ground, CA (US); Zhizheng LIU, San Jose, CA (US)

(73) Assignee: Infineon Technologies LLC, San Jose, CA (US)

(21) Appl. No.: 18/907,181

(22) Filed: Oct. 4, 2024

(51) Int. Cl. H10B 43/27; H01L 29/66; H01L 29/792; H10B 43/10

(52) U.S. Cl. CPC H10B 43/27; H10B 43/10; H10D 30/0413; H10D 30/69

(57) ABSTRACT

Semiconductor devices and methods of manufacturing the same are provided. The semiconductor device may include a first region including at least one non-volatile memory (NVM) transistor having a lower source/drain (S/D) junction and an upper S/D junction, a vertical channel disposed between the upper and lower S/D junctions and surrounded by a cylindrical memory film stack, and a gate layer disposed around the memory film stack, the device also include a second region including at least one logic transistor each having a gate dielectric layer overlying a horizontal channel, a gate layer, and a height-enhancement layer. Other embodiments are also described.

### CROSS-REFERENCE TO RELATED APPLICATIONS

None.

### TECHNICAL FIELD

This disclosure relates generally to semiconductor devices and more particularly pertaining to non-volatile memory devices having vertical channels integrated with logic complementary-metal-oxide-semiconductor (CMOS) devices, embedded or integrally formed on a single or multiple substrates, and methods of fabrication the same.

### BACKGROUND

Non-volatile memory (NVM) as a memory device is widely used for storing data in computer systems, and typically includes a memory array with a large number of NVM cells arranged in rows and columns, or other configurations. System-on-a-chip type architecture also increases electronic device functionality. Such architecture may incorporate, for example, a memory device on the same substrate as a logic device to reduce the cost of fabrication as well as increase communication bandwidth between the NVM and logic devices.

The integration of these dissimilar devices in a system-on-a-chip architecture is problematic because the fabrication process for the logic MOS device may hamper the fabrication process of the memory device and vice versa. Such a dilemma may occur, for example, when integrating the logic MOS gate oxide process module with the fabrication of a dielectric stack for a memory device. Also, channel and well implant processing for the logic devices may also be detrimental to the memory device dielectric stack while formation of the latter may be problematic for the former. As still another example, silicided contacts, which are advantageous for a logic transistor, may adversely affect a nonvolatile charge trap memory device.

Other than integration of a memory device into CMOS flow, the scaling of features in integrated circuits has been a driving force behind an ever-growing semiconductor industry. Scaling to smaller and smaller features enables increased densities of functional units on the limited real estate of semiconductor chips. The drive for ever-more capacity, however, is not without issue. Continued scaling of NVM devices, such as NOR flash memory, leads to word line (WL) pitch and bit line (BL)/source line (SL) pitch shrinkage. While scaling becomes increasingly significant, it may adversely affect the reliability of NVM devices by promoting breakdown voltage (BVdis) degradation, Icell degradation, and transient program disturb (TPD), amongst other potential defects. In some memory devices, vertical channel configuration is adopted to decouple channel length from die size scaling and to optimize the performance while scaling becomes increasingly significant.

It is, therefore, an object of the present disclosure to propose an integration scheme to incorporate NVM cells having vertical channels into a CMOS process flow effectively.

### BRIEF DESCRIPTION OF THE DRAWINGS

The present patent disclosure will be understood more fully from the detailed description that follows and from the accompanying drawings and the appended claims provided below, where:

FIG. 1 is a schematic diagram of an embodiment of an embedded NVM device;

FIG. 2A a schematic diagram of an embodiment of a portion an NVM array;

FIG. 2B is a representative block diagram illustrating a cross-section of two NVM transistors or devices in the NVM array depicted in FIG. 1;

FIG. 3 is a schematic diagram of NVM device 200 according to an embodiment of the present disclosure;

FIG. 4A is a representative block diagram illustrating a top view of NVM device 200 according to an embodiment of the present disclosure;

FIG. 4B is a representative block diagram illustrating a top view of a section 250 of NVM device 200 depicted in FIG. 3;

FIG. 5A-5E are representative block diagrams each illustrating a cross-section of a portion of NVM device 200 according to an embodiment of the present disclosure;

FIG. 6A-6B are flowcharts depicting a method of fabricating NVM device 900 including NVM cells with vertical channels according to an embodiment of the present disclosure; and FIG. 7A-7S are representative diagrams illustrating a portion of NVM device 900 at various points during its manufacture according to the method of fabrication of FIG. 6A-6B.

The features and advantages of embodiments of the present invention will become more apparent from the detailed description set forth below when taken in conjunction with the drawings. In the drawings, like reference numbers generally indicate identical, functionally similar, and/or structurally similar elements.

### DETAILED DESCRIPTION

This specification discloses one or more embodiments that incorporate the features of this invention. The disclosed embodiment(s) merely exemplify the present invention. The scope of the present invention is not limited to the disclosed embodiment(s). The present invention is defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Before describing the various embodiments in more detail, further explanation shall be given regarding certain terms that may be used throughout the descriptions.

The term “etch” or “etching” is used herein to generally describe a fabrication process of patterning a material, such that at least a portion of the material remains after the etch is completed. For example, it should be understood that the process of etching silicon involves the steps of patterning a masking layer (e.g., photoresist or a hard mask) above the silicon, and then removing the areas of silicon no longer protected by the masking layer. As such, the areas of silicon protected by the mask would remain behind after the etch process is complete. However, in another example, etching may also refer to a process that may or may not use a mask, and may or may not leave behind a portion of the material after the etch process is complete.

The above description serves to distinguish the term “etching” from “removing.” When removing a material, substantially all of the material is removed in the process. However, in some embodiments, ‘removing’ is considered to be a broad term that may incorporate etching.

The term “CMP” is used herein to generally describe a chemical mechanical polishing or planarization process used to smooth a surface on or over a substrate during semiconductor fabrication. The process generally uses combination of an abrasive and/or corrosive colloidal slurry in conjunction with mechanical forces provided by affixing the substrate to a dynamic polishing head pressing it against a rotating a polishing pad. The process removes material from the substrate thereby providing a planarized surface.

During the descriptions herein, various regions of the substrate upon which the memory cell, logic and high voltage transistors or devices or connection features are fabricated are mentioned. It should be understood that any number of regions may exist on the substrate and may designate areas having certain, types of devices or materials. In general, the regions are used to conveniently describe areas of the substrate that include similar devices and should not limit the scope or spirit of the described embodiments.

The terms “over”, “overlying”, “under”, “between”, and “on” as used herein refer to a relative position of one layer with respect to other layers. As such, for example, one layer deposited or disposed over or under another layer may be directly in contact with the other layer or may have one or more intervening layers. Moreover, one layer deposited or disposed between layers may be directly in contact with the layers or may have one or more intervening layers. Additionally, the relative position of one layer with respect to other layers is provided assuming operations deposit, modify and remove films relative to a starting substrate without consideration of the absolute orientation of the substrate.

The terms “deposit” or “dispose” are used herein to describe the act of applying a layer of material to the substrate. Such terms are meant to describe any possible layer-forming technique including, but not limited to, thermal growth, sputtering, evaporation, chemical vapor deposition, epitaxial growth, electroplating, etc. According to various embodiments, for instance, deposition may be performed according to any appropriate well-known method. For instance, deposition can comprise any process that grows, coats, or transfers material onto a substrate. Some well-known technologies include physical vapor deposition (PVD), chemical vapor deposition (CVD), electrochemical deposition (ECD), molecular beam epitaxy (MBE), atomic layer deposition (ALD), and plasma-enhanced CVD (PECVD), amongst others.

The “substrate” as used throughout the descriptions is most commonly thought to be silicon. However, the substrate may also be any of a wide array of semiconductor materials such as germanium, gallium arsenide, indium phosphide, etc. In other embodiments, the substrate may be electrically non-conductive such as a glass or sapphire wafer.

As used herein, “mask” may comprise any appropriate material that allows for selective removal (e.g., etching) of an unmasked portion a material. According to some embodiments, masking structures may comprise a photoresist such as Poly(methyl methacrylate) (PMMA), Poly(methyl glutarimide) (PMGI), a Phenol formaldehyde resin, a suitable epoxy, etc., or a hardmask including silicon nitride.

### Summary of Subject Matter

According to one embodiment of a semiconductor device, the semiconductor device may include a first region having at least one non-volatile memory (NVM) transistor formed over a substrate, in which each NVM transistor may have a lower source/drain (S/D) junction and an upper S/D junction, a vertical channel disposed between the upper and lower S/D junctions, a cylindrical memory film stack surrounding the vertical channel, and a gate layer disposed around the memory film stack. The device also has a second region including at least one logic transistor that includes a gate dielectric layer overlying a horizontal channel, a gate layer, and a height-enhancement (HE) layer, in which the at least one NVM transistor in the first region and the at least one logic transistor in the second region have substantially a same device height.

In one embodiment, the semiconductor device in which the at least one logic transistor includes a low voltage (LV) transistor and a high voltage (HV) transistor, in which the LV transistor has a thinner gate dielectric layer than the HV transistor's.

In one embodiment, the semiconductor device in which the gate layers of the at least one logic transistor are multi-layered and each has a metal gate layer overlying a doped silicon gate layer.

In one embodiment, the semiconductor in which the first region further includes a word line (WL) extending and coupling to the gate layers of the at least one NVM transistors in a first direction, in which the gate layers of the at least one NVM transistors in the first direction form a portion of the WL.

In one embodiment, the semiconductor device in which the first region further includes a source line (SL) extending and coupling to lower S/D junctions of at least one NVM transistors in a second direction, in which the lower S/D junctions of the at least one NVM transistors in the second direction form a portion of the SL, and a bit line (BL) extending and coupling to upper S/D junctions of at least one NVM transistors in the second direction, in which the first and second directions are substantially perpendicular to one another.

In one embodiment, the semiconductor device in which the cylindrical memory film stack includes an oxide-nitride-oxide (ONO) stack having a charge-trapping layer disposed uprightly from a top surface of the substrate.

In one embodiment, the semiconductor device in which the HE film includes silicon nitride and is configured to protect the gate layer and the gate dielectric layer in the second region while the at least one NVM transistor is being formed in the first region and control channel length of the vertical channel of the at least one NVM transistor.

In one embodiment, the semiconductor device in which the lower S/D junction of the at least one NVM transistor and the horizontal channel of the at least one logic transistor are formed at least partially buried within the substrate.

In one embodiment, the semiconductor device in which the vertical channel has a circular cross-section and includes doped silicon of a positive type, and in which the lower and upper S/D junctions include doped silicon of a negative type.

In one embodiment, the semiconductor device in which the vertical channel further includes a channel filler including a dielectric layer surrounded by an outer channel shell including doped silicon of a positive type.

In one embodiment, the semiconductor device in which the charge-trapping layer is configured to retain electrical charges in more than one physically and spatially separated regions, and the at least one NVM transistor is configured to store more than one bit of binary values.

In one embodiment, the semiconductor device in which the BL is coupled to the upper S/D junction of the NVM transistor via a BL connect, and the BL connect couples two neighboring NVM transistors to the BL.

In one embodiment, the semiconductor device in which the two neighboring NVM transistors are respectively coupled to two neighboring SLs, and the two neighboring SLs are electrically insulated from one another.

In one embodiment, the semiconductor device in which the semiconductor device is a bi-directional transistor device, and the lower and upper S/D junctions are configured to function as both a source or a drain of the bi-directional transistor device.

In one embodiment, the semiconductor device in which the ONO stack is surrounded by a high-K dielectric layer and the gate layer includes a layer of tungsten, making the at least one NVM device a high-K metal gate device.

In one embodiment, the semiconductor device in which the at least one NVM transistor is arranged in one single layer and vertically disposed between the BLs and SLs.

According to one embodiment of an embedded semiconductor device, the embedded semiconductor device may include a non-volatile memory (NVM) array disposed in a core region of a substrate having a plurality of source lines (SLs) extending in a first direction, wherein adjacent SLs are insulated by shallow trench isolations (STIs), NVM transistors formed overlying the plurality of SLs, each NVM transistor having a lower source/drain (S/D) junction, a vertical channel surrounded by a memory film stack and a metal gate layer, and an upper S/D junction overlying the vertical channel, a plurality of word lines (WLs) coupling to the metal gate layers of the NVM transistors and extending in a second direction, and a plurality of bit lines (BLs) overlying the upper S/D junctions and the metal gates of the NVM transistors, in which the BLs are coupled to the upper S/D junctions of at least one NVM transistors and extend in the first direction and at least one logic transistor disposed in a periphery region of the substrate, in which each logic transistor has a gate dielectric layer overlying a horizontal channel, a gate layer, and a height-enhancement (HE) layer.

In one embodiment, the embedded semiconductor device in which the second direction is substantially perpendicular to the first direction.

In one embodiment, the embedded semiconductor device in which the NVM transistors in the core region and the at least one logic transistor in the periphery region have substantially a same device height and arranged in one single layer and vertically disposed between the BLs and SLs.

According another embodiment of a semiconductor device, the semiconductor device may include a plurality of non-volatile memory (NVM) transistors arranged in rows and columns formed in a substrate, in which each NVM transistor has a lower source/drain (S/D) junction, a vertical channel surrounded by a memory film stack and a metal gate layer, and an upper S/D junction overlying the vertical channel, a plurality of logic transistors formed in the substrate, in which each logic transistor has a gate dielectric layer overlying a horizontal channel, a gate layer, and a height-enhancement (HE) layer, a plurality of word lines (WLs), in which each couples NVM transistors of a same row, in which metal gate layers of the NVM transistors of the row form a portion of the WLs, a plurality of source lines (SLs), each coupling NVM transistors of two adjacent columns, in which lower S/D junction of the NVM transistors of the two adjacent columns form a portion of the SLs, and a plurality of bit lines (BLs), each coupling NVM transistors of at least one column via a plurality of BL connects.

In one embodiment, the semiconductor device in which the plurality of NVM transistors are formed overlying the plurality of SLs formed at least partly within the substrate, the plurality of SLs and BLs propagate in a same direction, and the plurality of WLs and BLs propagate in a perpendicular direction.

In one embodiment, the semiconductor device in which the plurality of NVM transistors and the plurality of logic transistors have substantially a same device height and arranged in one single layer disposed vertically between BLs and SLs.

### Description of Embodiments

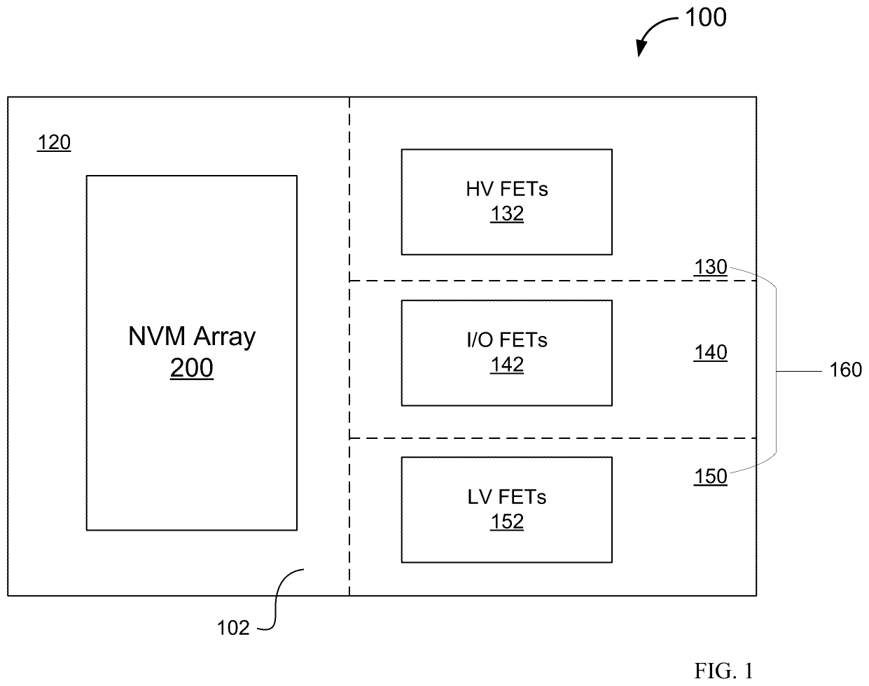

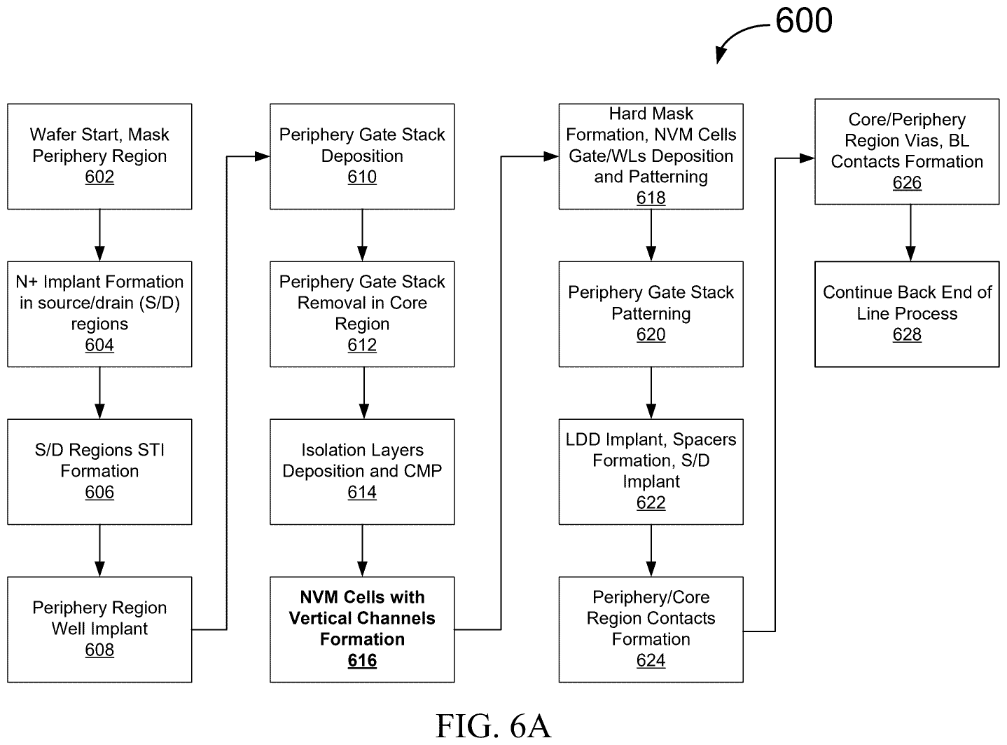

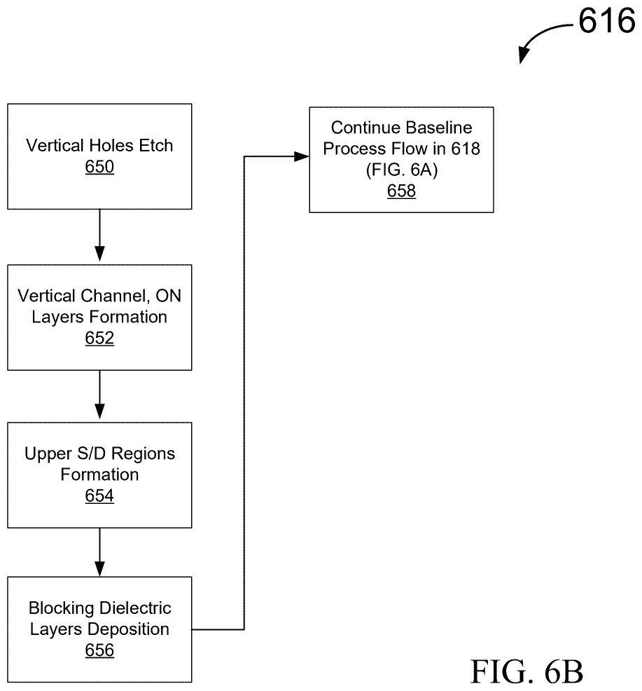

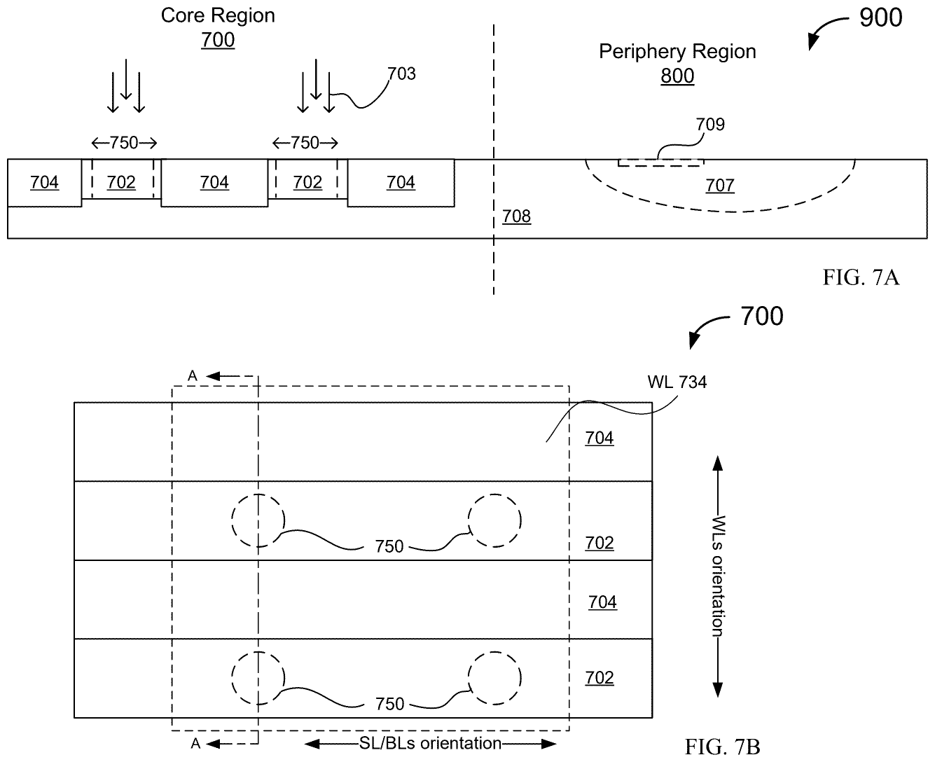

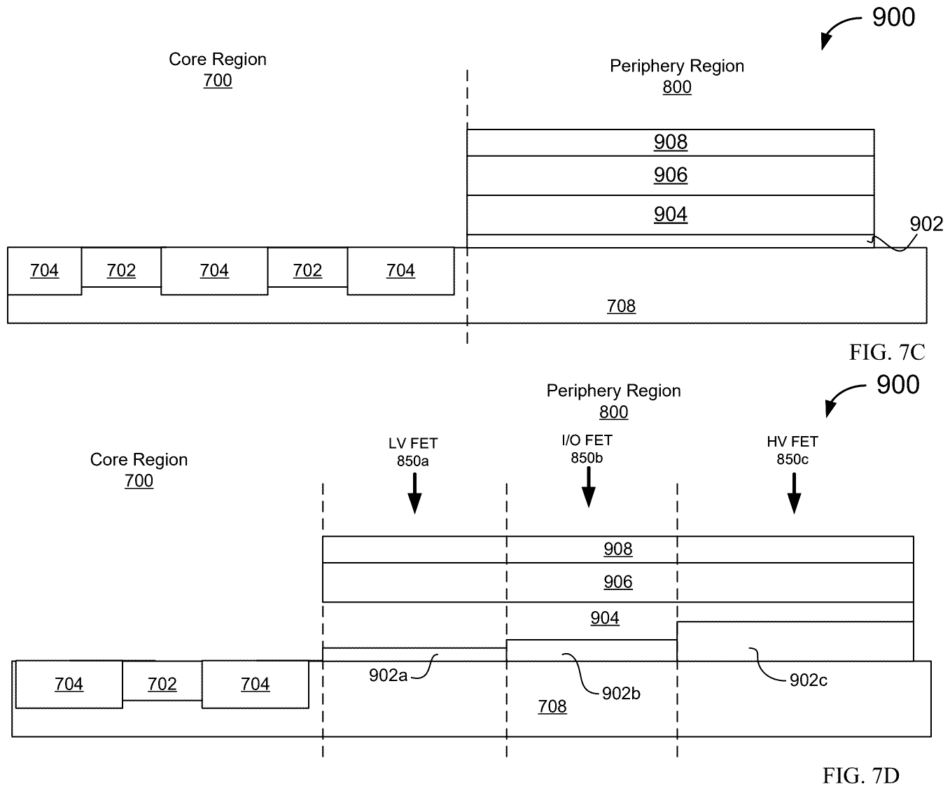

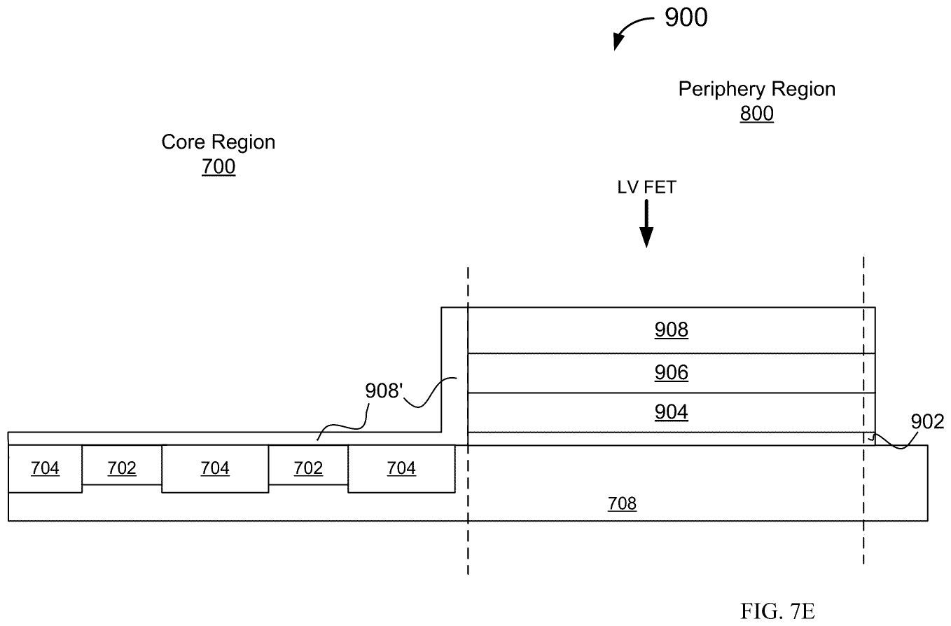

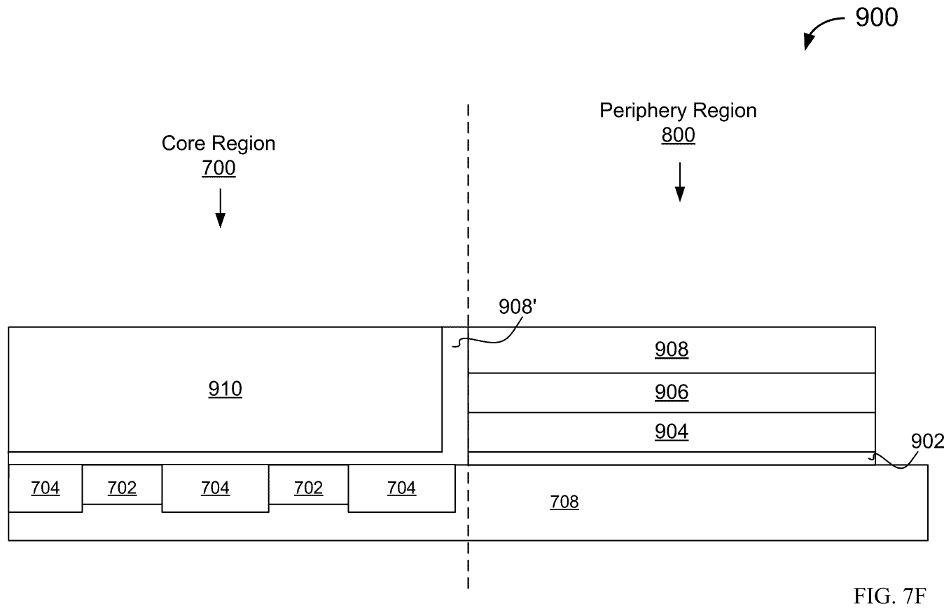

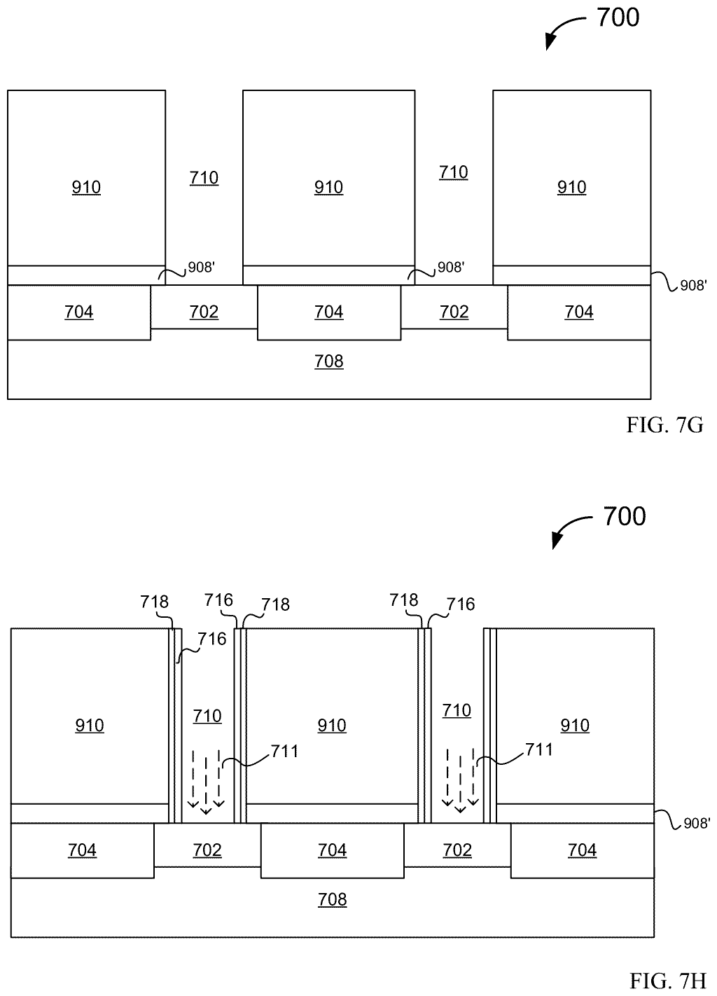

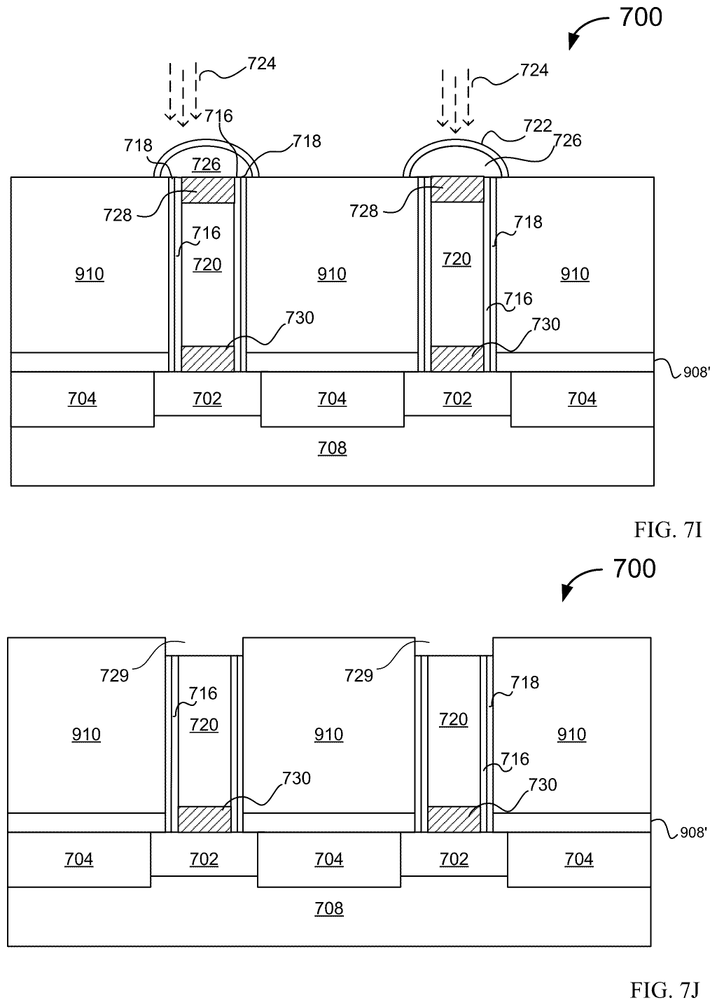

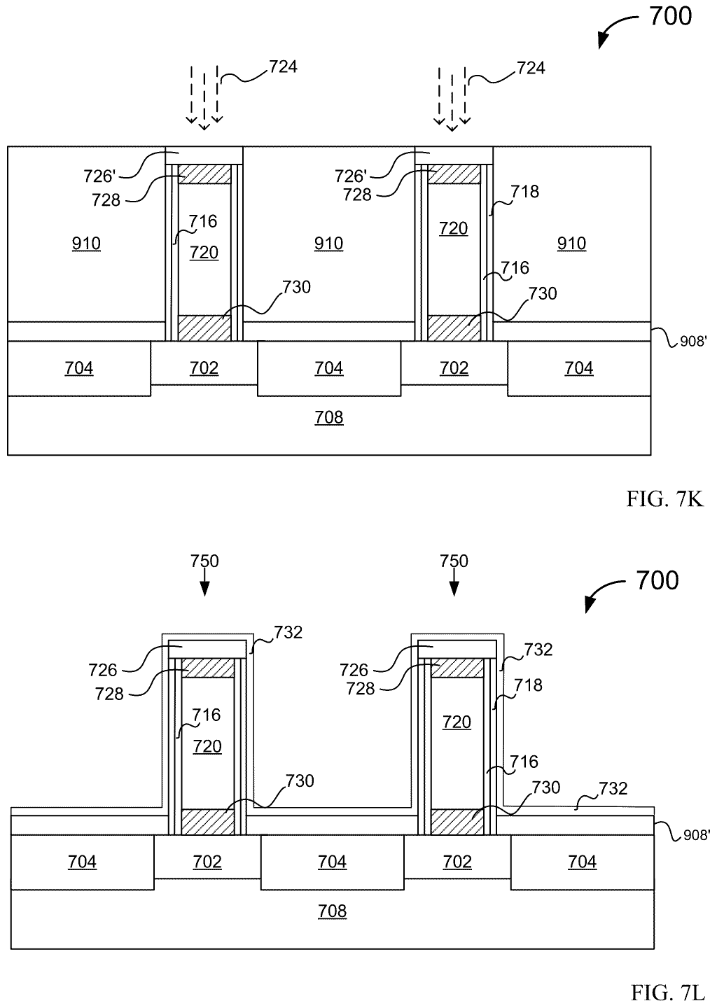

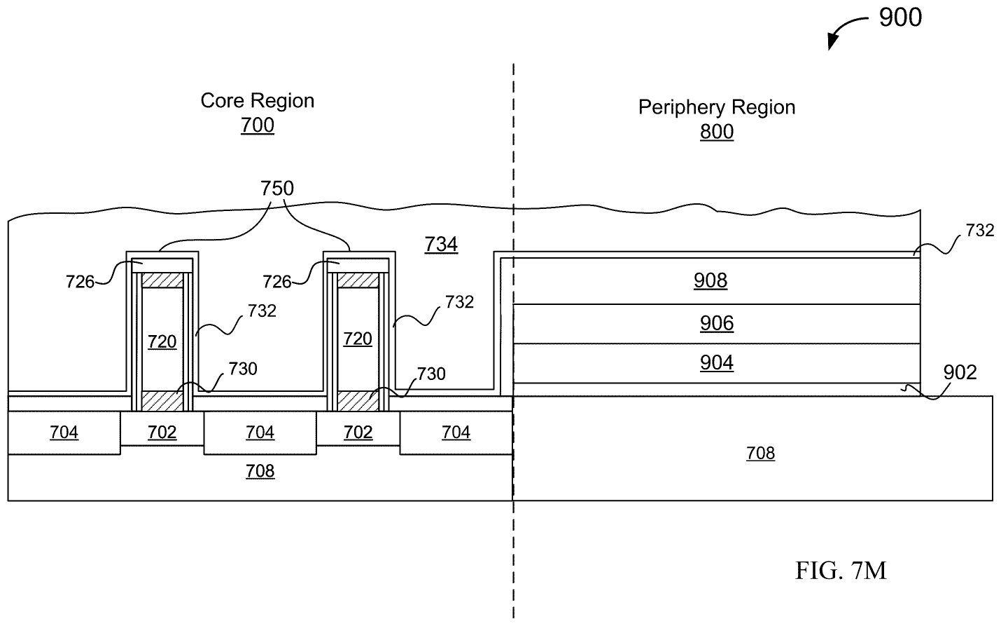

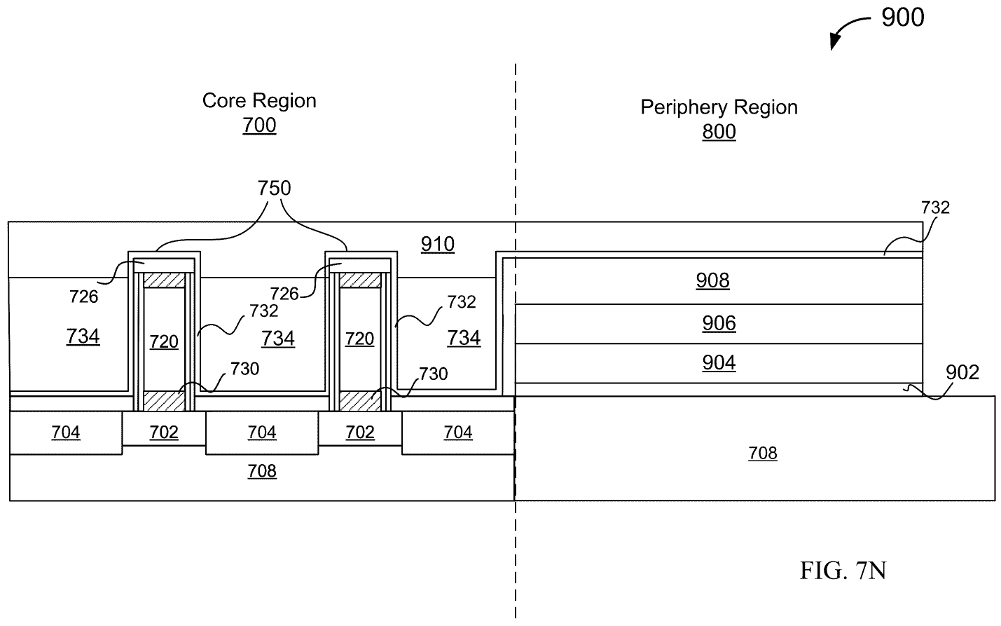

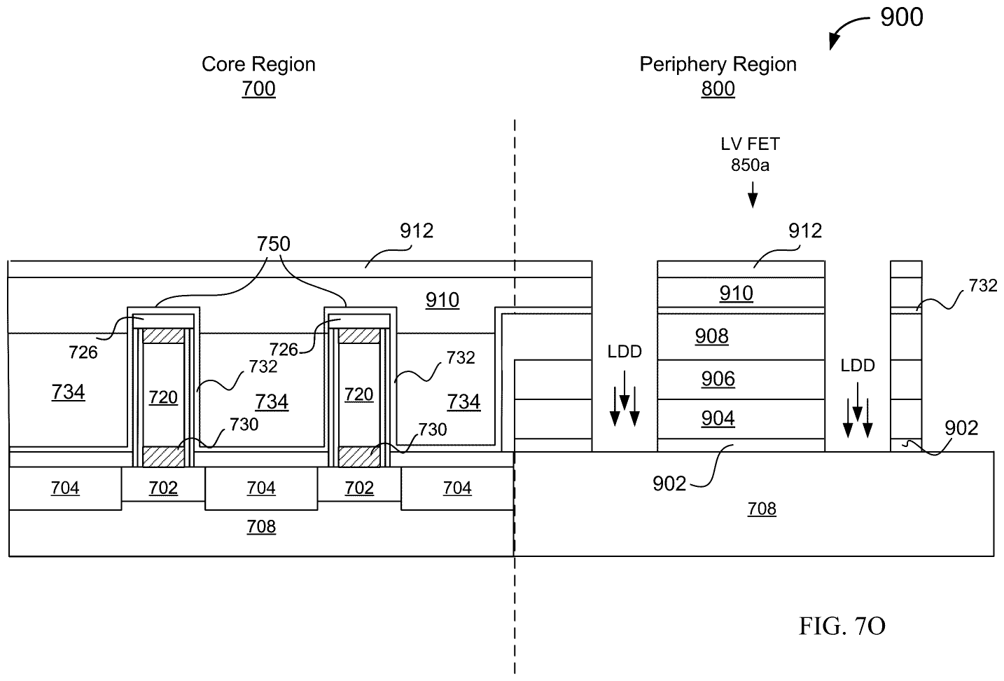

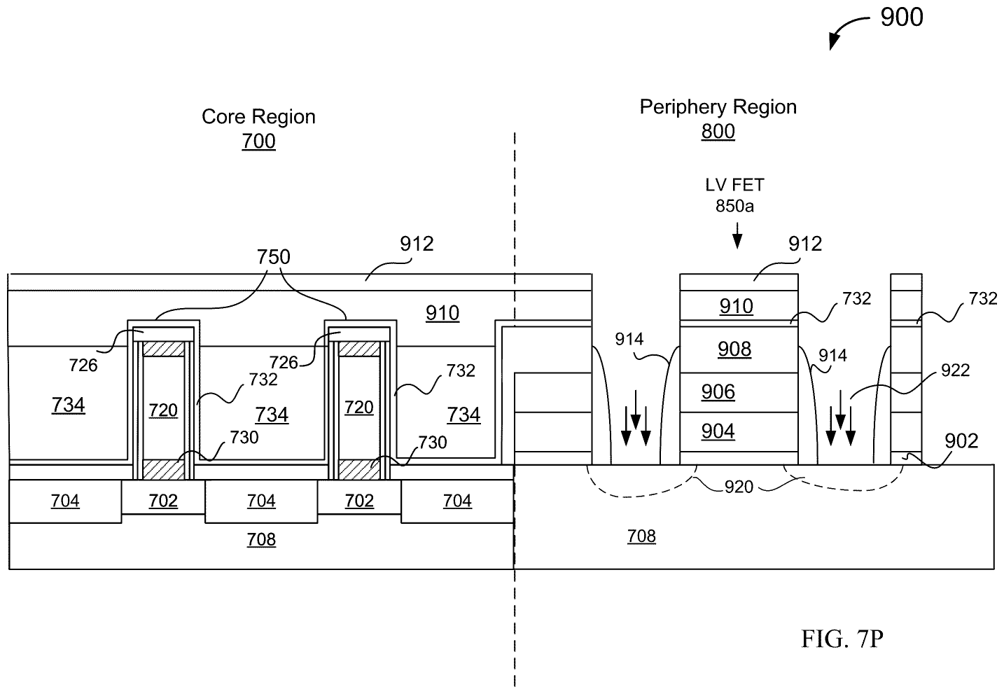

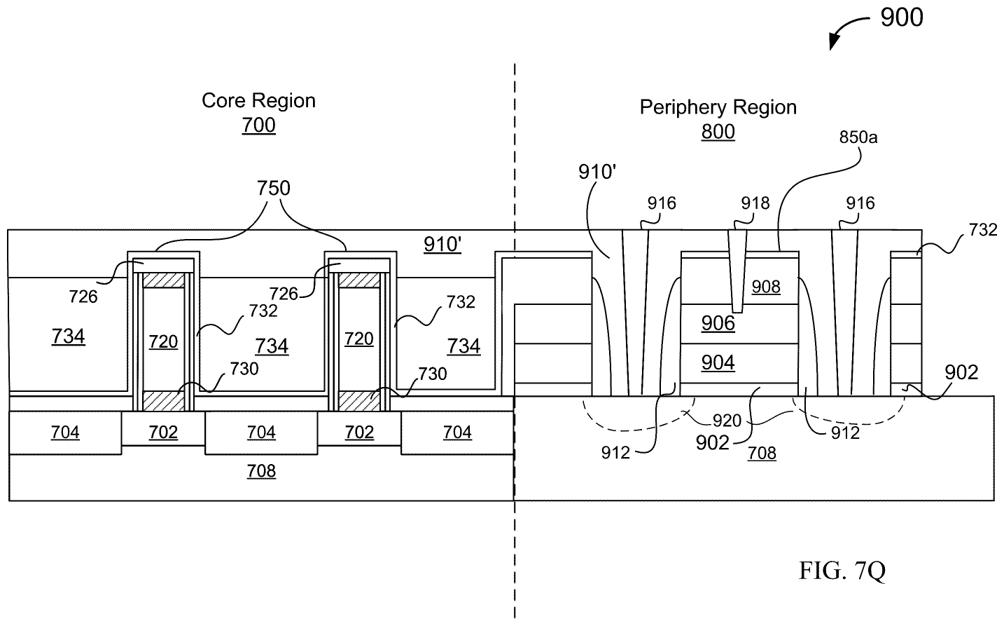

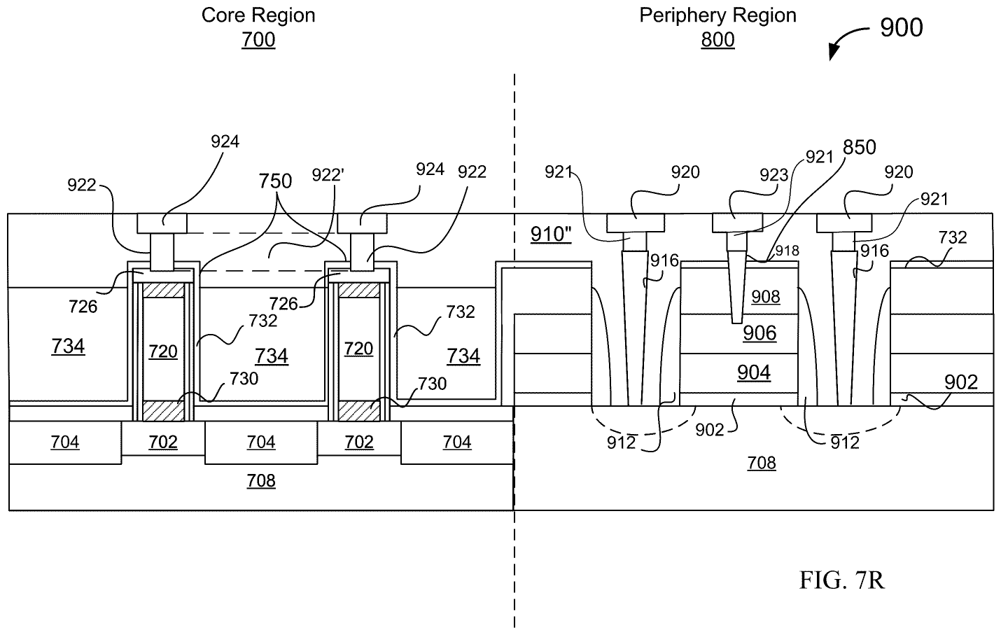

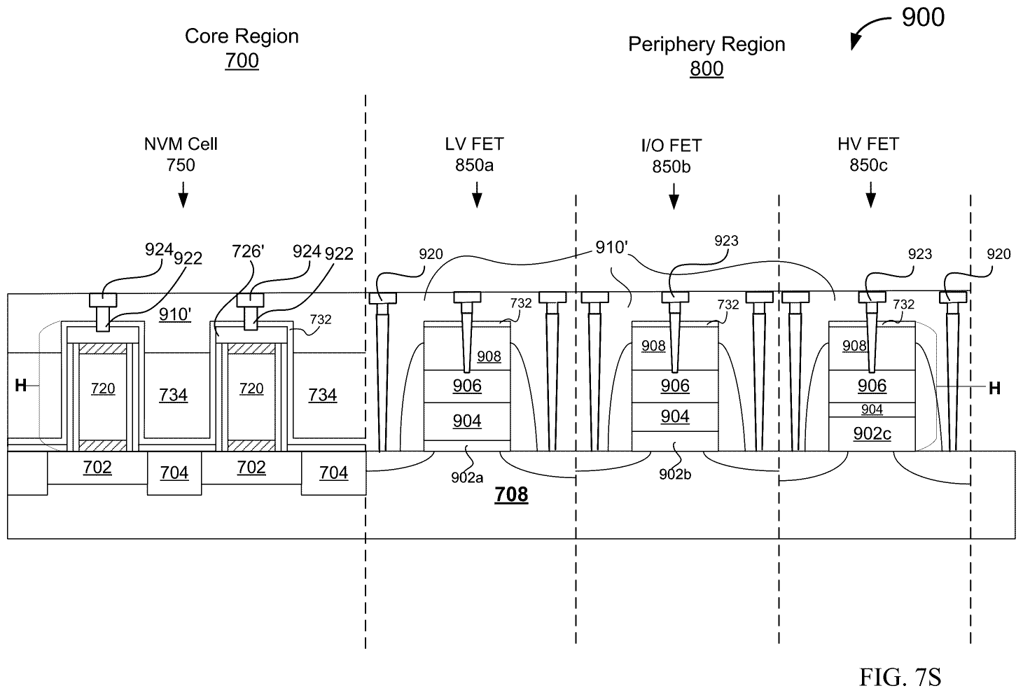

FIG. 1 is a representative block diagram illustrating embedded NVM device 100, as fabricated in FIG. 6A-6B and 7A-7S. In one embodiment, embedded NVM device 100 is formed in a single semiconductor die or substrate 102. The semiconductor die or substrate 102 is at least divided into the first or memory or core region 120 for the embedded memory, such as NVM array or device 200 and the second or periphery or CMOS or logic region 160 including but not limited to HV area 130 for HV_MOS transistors 132, I/O area 140 for I/O_MOS transistors 142, and LV area 150 for LV_MOS transistors 152, respectively. In some embodiments, there may be MOS transistors in the first region 120 as some NVM memory arrays may include HV select transistors. For example, a two-transistor (2T-memory gate/select gate) configuration memory array having HV transistors as the select transistors. It will be the understanding that embedded NVM device 100 may include other devices, such as processors, power circuits, etc. In one embodiment, NVM array 200 may include one or more NVM cell having vertical channel, as will be explained in later sections of this patent document.

In various embodiments, one or more of the first and second regions 120 and 160 may be overlapping spatially, and the HV area 130, I/O area 140, and LV area 150 may be overlapping. In will be the understanding that embodiment illustrated in FIG. 1 is only exemplary, and one or more of the first region 120 and the HV area 130, I/O area 140, and LV area 150 may be disposed in any location of single substrate 102 or multiple substrates, and may be made up of various different number of regions.

In one embodiment, HV_MOS 132 may be provided with a high voltage in a range of 4.5 V-12 V or other voltages in order to program and/or erase NVM cells or transistors (not shown in FIG. 1) in NVM array 200. I/O_MOS 142 may be coupled to I/O interface and provided with an operation voltage in a range of 1.6 V-3.6 V or other voltages. LV_MOS 152 may be provided with an operation voltage in a range of 0.8 V-1.4 V or other voltages for various operations and connections.

In this disclosure, processes to embed NVM devices or transistors having vertical channels into a CMOS process that includes a thin gate oxide for the LV devices and/or a thick gate oxide for the I/O and HV devices are introduced and described.

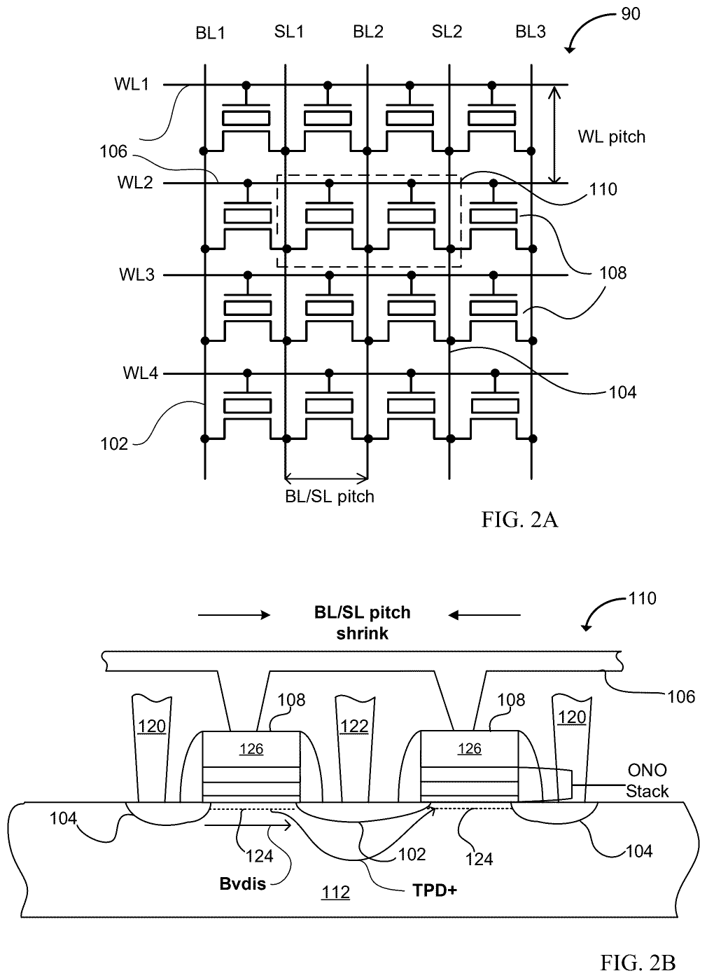

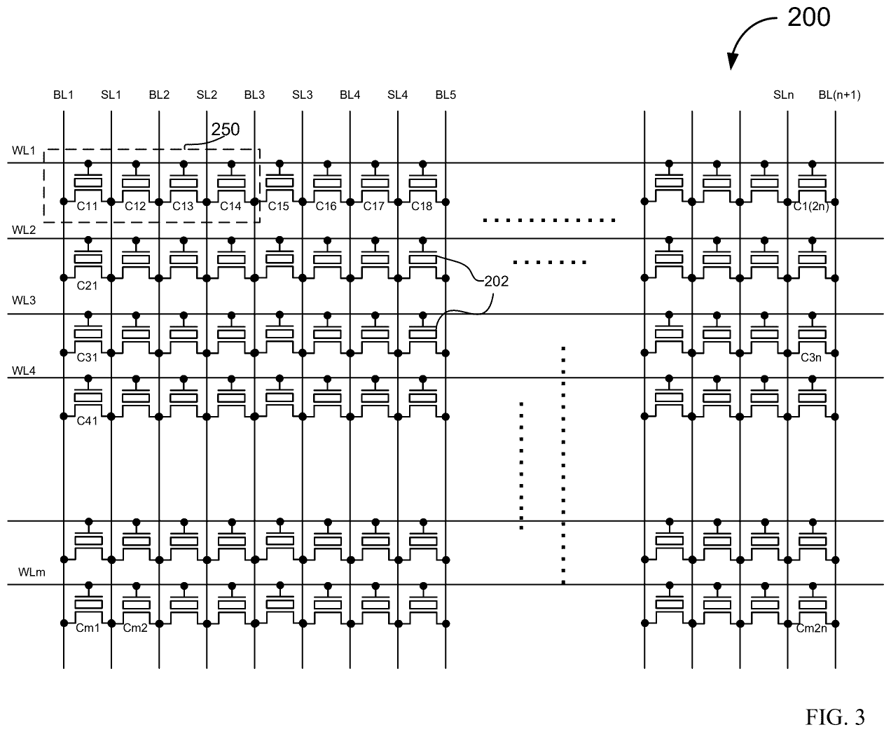

FIG. 2A illustrates a schematic block diagram of a portion of an NVM device 90 according to an embodiment. FIG. 2B illustrates a representative cross-section of two adjacent NVM transistors 108 in area 110 along or connected to the same word line WL2 at each of its gates. In one embodiment, NVM device 90 includes NVM transistors 108 arranged in rows (horizontal) and columns (vertical), connected with word lines or regions (WLs) 106, bit lines or regions (BLs) 102, source lines or regions (SLs) 104, and/or other connections. In embodiments, NVM device 90 may be configured to function as NOR flash memory, EEPROM, or other types of non-volatile memory devices. It may also include one or more memory array(s) and be organized in multiple erase sectors. NVM transistors 108 may be field-effect transistors having a non-conducting charge-trapping layer(s) or a floating gate layer to trap charges. In some embodiments, NVM device 100 may be embedded in another semiconductor device or system, such as micro-controllers that includes MOSFETs and other semiconductor devices. As shown in FIG. 2A, WLs 106 connect NVM transistors 108 extended or propagated in one direction and BLs 102 and SLs 104 connect NVM transistors 108 in an opposite direction. It would be the understanding that this particular arrangement is shown as an example and one having ordinary skill in the art would recognize other arrangements may be adopted. In embodiments, NVM transistors 108 may be a bi-directional device, capable of storing one or more bit(s) of binary information or bit values. In those configurations, BLs 102 and SLs 104 may be interchangeable functionally and referred to as BL/SLs collectively throughout this patent document.

As best shown in FIG. 2B, NVM transistors 108 adopt a planar or two-dimensional (2D) structure in which channels 124 run horizontally or parallel to the substrate 112 surface between BL 102 to SL 104. It will be the understanding that, depending on the device design, BLs 102 or SLs 104 may also be doped regions within substrate 112, functionally performing as source or drain regions of NVM transistors 108. In embodiments, there may be BL connects 122 and SL connects 120 to complete the BLs 102 and SLs 104 connection. WLs 106 are coupled to gate 126 of NVM transistors and extend perpendicularly to BL/SLs.

One of the main challenges of scaling semiconductor devices, such as NVM device 100, is that the size of NVM transistors 108 is much reduced and packed closer together. The reduction in size may shorten the channel 124 length while densely packing NVM transistors 108 may reduce WL pitch and BL/SL pitch. The excessive scaling may adversely affect reliability and performance of the device by worsening transient program disturb (TPD+) of neighboring NVM transistors 108, breakdown voltage (BVdis) degradation, adjacent word line disturb (AWD), and sensing current (Icell) degradation, among other potential defects.

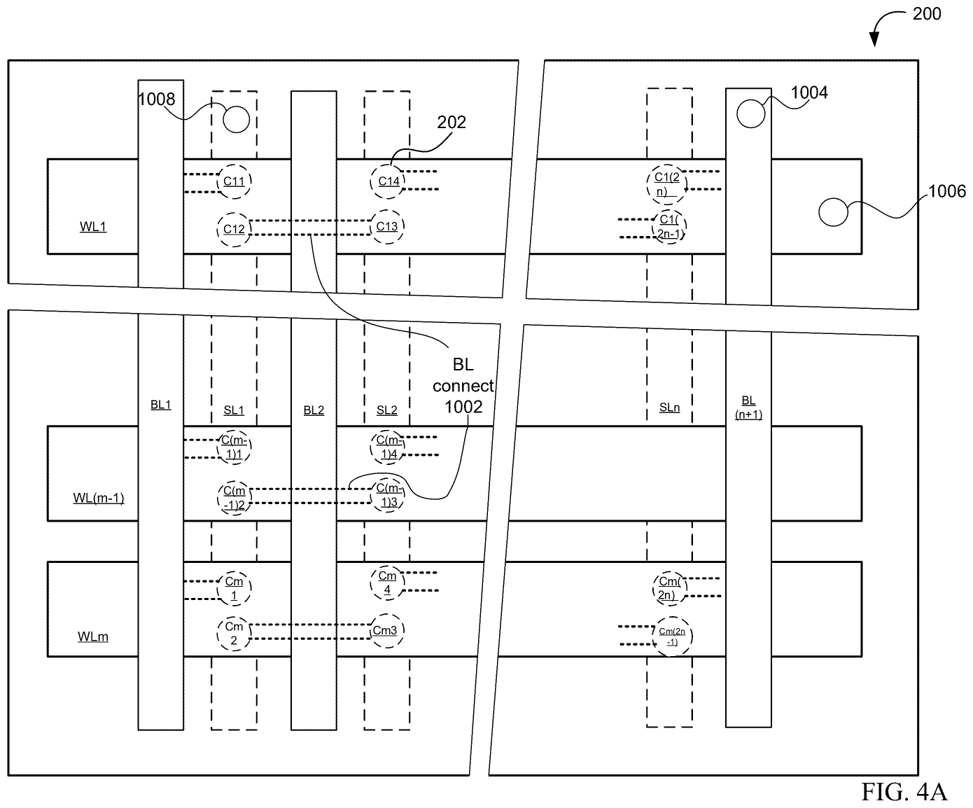

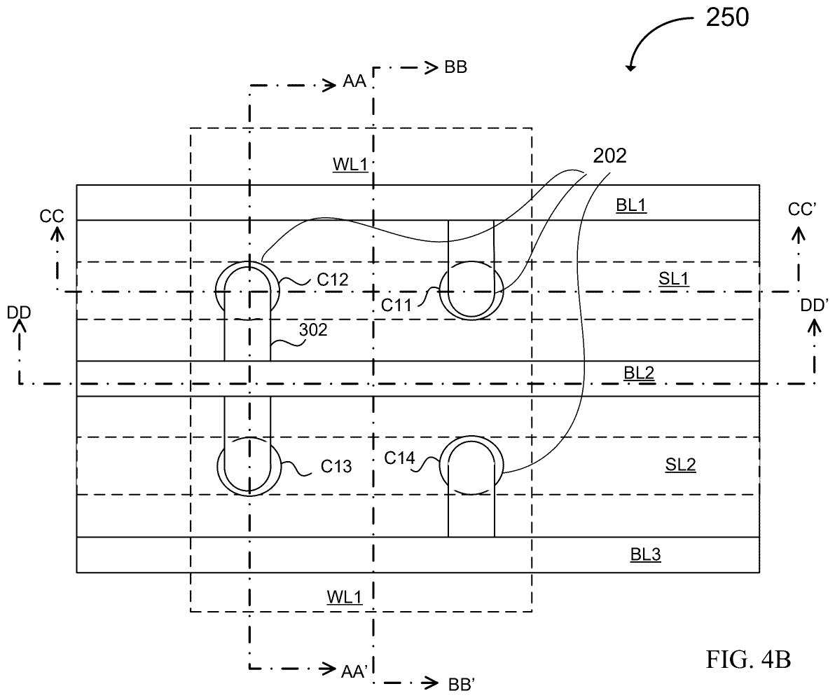

FIG. 3 is a schematic block diagram illustrating an NVM array 200 having m×WLs, n×SLs, and (n+1) BLs. FIG. 4A is a representative block diagram illustrating a top view of NVM array 200 of FIG. 3, or similar NVM arrays. NVM array 200 may be embedded in NVM device 100 as best shown in FIG. 1, or similar embedded NVM devices. NVM cells 202, as will be shown and described in later sections, each includes a vertical channel disposed and extending vertically between source/drain regions of the device. As best shown in FIG. 3, NVM cells 202 are connected along horizontal rows by word lines (WLs) and vertical columns by bit lines (BLs) and source lines (SLs). It would be the understanding that the terms “columns” and “rows” of NVM array 200 may be used interchangeably depending on the orientation of NVM array 200. It would also be the understanding that NVM cells 202 may be arranged and connected in other ways known by one having ordinary skill in the art, without deviating from the principles of this patent disclosure.

In one embodiment, NVM array 200 includes m rows and 2n columns of NVM cells 202, or 2n rows and m columns, depending on the orientation of NVM array 200. Each NVM cells 202 may include a vertical channel connecting a lower S/D region (SL) in the substrate and an upper S/D region (to BL). In some embodiments, NVM cells 202 may be bi-directional devices and store two physical bits in the memory layer, such as charge trapping layer, in which SL and BL are interchangeable functionally. These two independent physical bits (bit1 and bit2) can be independently read by running a current through vertical channel in different directions (up or down), or other read/sensing algorithms known by one having ordinary skill in the art. In embodiments, each NVM cell 202 may store one or multiple bits of binary data, corresponding to charges trapped in one or more spatially separated locations in the charge trapping layer of the NVM cell 202. Referring to FIG. 3, in a single row of NVM cells 202 connected to a single WL, for example WL1, there are 2n×NVM cells 202 (viz. C11−C1(2n)). In a single column of NVM cells 202, wherein each NVM cell 202 is coupled to the same BL and SL (e.g. BL1 and SL1), there are m x NVM cells (viz. C11−Cm1). In this particular embodiment, there are a total of (m×2n) NVM cells 202 in NVM array 200, wherein adjacent cells (e.g. C12 and C13) of the same row may share either one BL or one SL.

Referring to FIG. 4A, SLs and BLs are arranged to extend or propagate in the same direction (vertically as shown in FIG. 4A), whereas WLs are arranged to extend or propagate in a perpendicular direction (horizontally) to both SLs and BLs. Each NVM cell 202 is fabricated overlying its corresponding SL, which also functions as lower S/D region providing electrical signals or bias to one end or the lower end of NVM cells 202. The upper end or upper S/D region of each NVM cell 202 is coupled to its corresponding BL via BL connect 1002 as best shown in FIG. 4A. In one embodiment, NVM cells 202 are arranged in one single layer and disposed vertically between SLs and BLs. In embodiments, BLs provide electrical signals or bias to the upper end of NVM cells 202 at each of their upper S/D regions. WLs are formed vertically between SL (within or buried in substrate) and BLs, surrounding the ONO stack and vertical channel of each NVM cell. In embodiments, WLs function as the gate for each NVM cell 202, providing the same electrical signal and bias to each NVM cell 202 along one WL. As best shown in FIG. 4A, there are WL contact 1006, SL contact 1008, and BL contact 1004 in one or more WLs, SLs, and BLs, respectively.

Contacts 1004, 1006, 1008 are configured to provide an interface to receive or transmit electrical signal, pulse, or bias from or to circuits outside NVM array 200, such as logical region 160 of NVM device 100 as best shown in FIG. 1. Electrical signals received through WL contact 1006 of WL1 will be provided to gates of NVM cells C11, C12, . . . , C1n of row 1. Similarly, electrical signals received through SL contact 1008 of SL1 will be provided to lower S/D regions of NVM cells C11, C12, . . . Cm1, Cm2 of columns 1 and 2 of NVM array 200. Electrical signals received through BL contact 1004 of BL1 will be provided to upper S/D regions of NVM cells C11, C21, . . . Cm1 of column 1 of NVM array 200.

FIG. 4B is a block diagram illustrating a top view of a section 250 of NVM array 200 (as best shown in FIG. 4A) including four adjacent NVM cells 202 viz. C11, C12, C13, and C14, all along WL1. Each NVM cell 202 adopts a cylindrical shape having a circular or an oval shaped planar cross-section. As best shown in FIGS. 3 and 4A, C11 and C12 shares a source line SL1; and C13 and C14 shares an adjacent source line SL2. In one embodiment, source lines, such as SL1, are disposed underneath NVM cells 202 or buried within the substrate. BLs, such as BL1, are disposed above NVM cells 202 and are connected to NVM cells 202 via BL connects 302. As best shown in FIG. 4B, NVM cell C11 is coupled to BL1 and NVM cells C12 and C13 are coupled to BL2 via their respective BL connects 302. In embodiments, NVM cells 202 are bi-directional devices in which current may run in both directions between SLs and BLs. Therefore, SLs and BLs may be functionally interchangeable and only physically or structurally distinguishable.

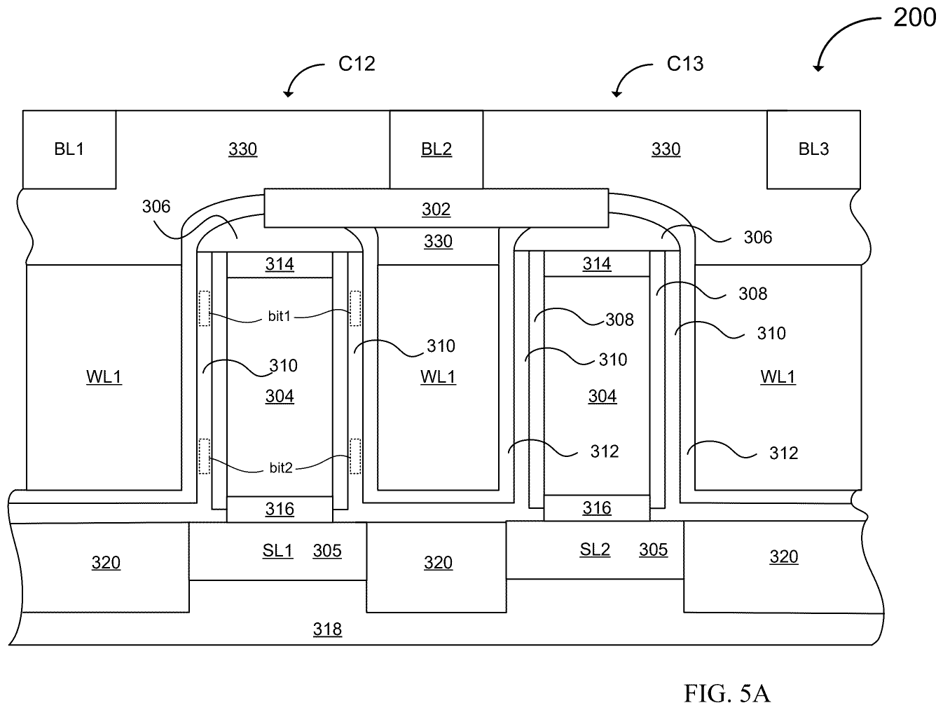

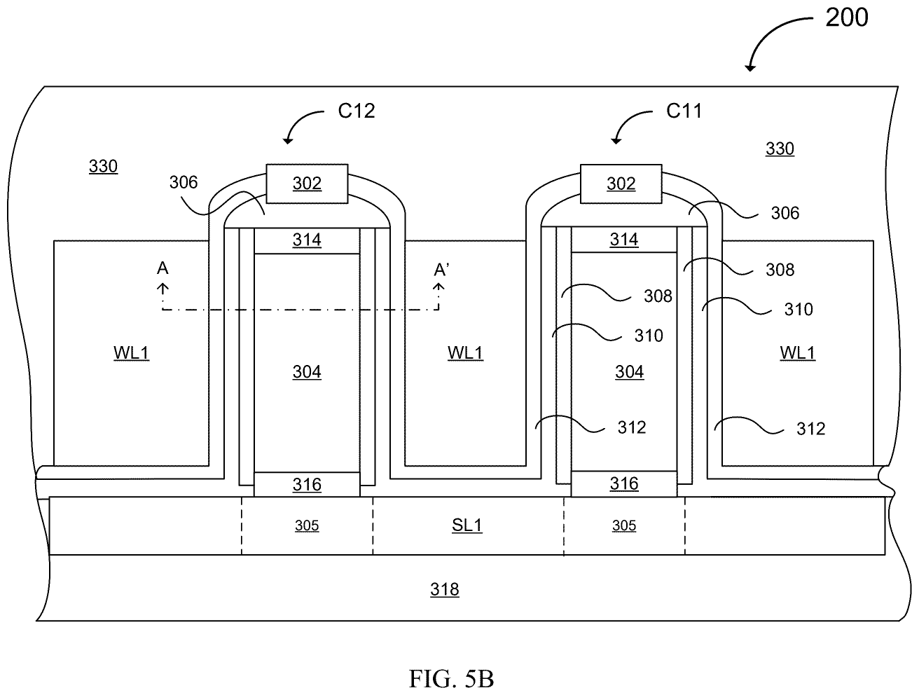

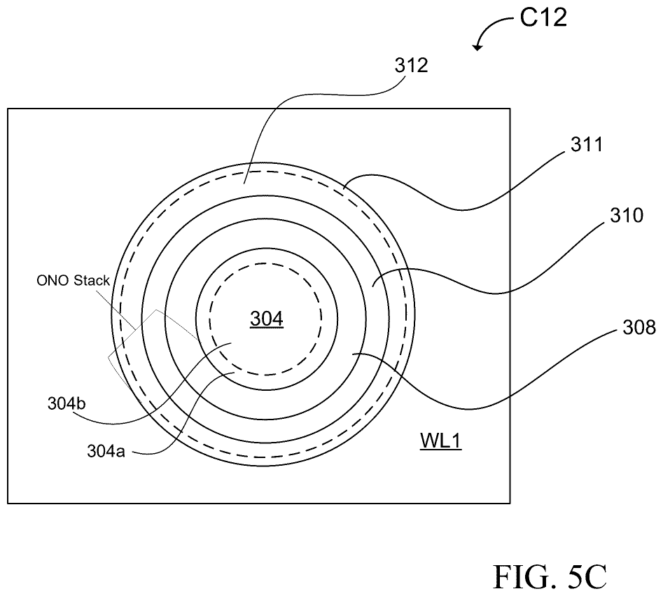

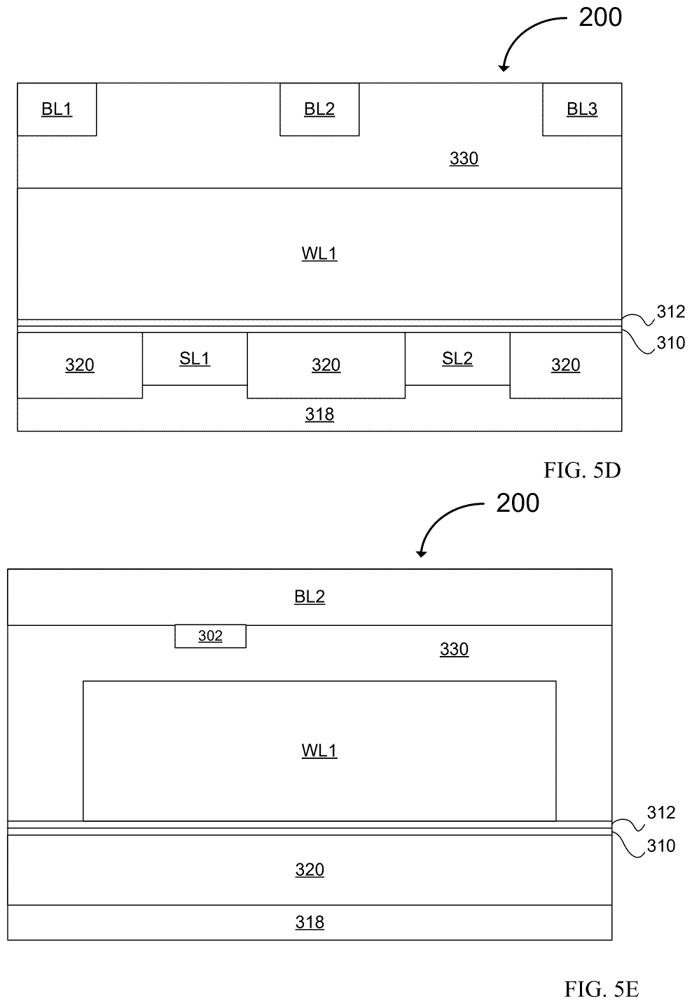

FIG. 5A is a representative block diagram illustrating a vertical cross-sectional view of NVM array 200 along cutting plane line AA-AA′ in FIG. 4B. As best shown in FIG. 5A, NVM cell C12 and C13 are formed adjacent to one another over substrate 318. In one embodiment, NVM cell 202, such as C13, includes source line SL2 that further includes heavily doped silicon or similar semiconductor material such as germanium, silicon-germanium or a Group III-V compound semiconductor material, formed within substrate 318 and upper source/drain (S/D) region 306 connected by vertical channel 304. Buried source lines, such as SL2, may serve a dual function of connecting NVM cells 202 along a column or row as previously explained and acting as another source/drain region for NVM cells 202. Throughout this patent document, buried source lines may also be referred to as lower S/D region 305 of NVM cell 202. In a bi-directional device, such as NVM cell 202, upper and lower S/D regions 306 and 305 may function as source or drain respectively in different operation settings. Within substrate 318, lower S/D regions 305 of adjacent NVM cells 202 are electrically isolated by shallow trench isolation (STIs) structures 320. In one embodiment, intervening structure upper lightly doped S/D 314 is formed between vertical channel 304 and upper S/D region 306. Similarly, lower lightly doped S/D 316 is formed between vertical channel 304 and lower S/D region 305. In one embodiment in which NVM cell 202 is an n-channel device, upper and lower S/D regions 306 and 305 are doped heavily with n-type dopants including but not limited to arsenic and phosphorus while lower and upper lightly doped S/D 314 and 316 are made of lightly doped semiconducting material with the same or different n-type dopants. Vertical channels 304 adopt a cylindrical shape and may include semiconducting material such as silicon with p-type dopants, including but not limited to boron. One having ordinary skill in the art would recognize that dopants in upper and lower S/D regions 306 and 305, upper and lower lightly doped S/D 314 and 316, and vertical channels 304 may have dopants of opposite or different types when NVM cells 202 are p-channel devices. One of the advantages of having vertical channel, such as vertical channel 304, is that channel length may be independent from scaling of NVM cells 202, such as shrinkage of WL pitch and BL/SL pitch.

Still referring to FIG. 5A, cylindrical vertical channel 304 is surrounded by a memory film stack of three dielectric layers, viz. tunnel oxide layer 308, charge-trapping layer 310, and blocking dielectric layer 312, forming an ONO stack. In one embodiment, tunnel oxide layer 308 may include silicon oxide or other dielectric materials. Charge-trapping layer 310 may be single or multiple layered including silicon nitride, oxynitride, or combinations thereof, and trap charges injected from vertical channel 304. In another embodiment, instead of an ONO stack, the memory film stack may include one or more layers of ferroelectric film (not shown in FIG. 5A), including such as hafnium dioxide (HfO₂). Optionally having one or more layer of dielectric, such as silicon oxide or oxynitride, disposed between vertical channel 304 and the ferroelectric film as an interfacial film or layer. Threshold voltage (VT) and drain current (ID) values of NVM cell 202 may change at least partly due to the amount of trapped charges. Through proper biasing, NVM cell 202 can store one or more spatially separated physical bits (bit1 and bit2 as shown in NVM C12) as charges at opposite ends of the charge-trapping layer 310. These two independent physical bits (bit1 and bit2) can be independently read by running a current through the vertical channel 304 in different directions (bi-directional), or other read/sensing algorithms known by one having ordinary skill in the art. Blocking dielectric layer 312 may include silicon oxide and may be multi-layered including optionally a high K dielectric layer. The high-K dielectric layer may include but not limited to, aluminum oxide, hafnium oxide, zirconium oxide, hafnium silicate, hafnium oxy-nitride, hafnium zirconium oxide, and lanthanum oxide. As best shown in FIG. 5A, blocking dielectric layers 312 of NVM cells C12 and C13 are surrounded or encapsulated by WL1. In one embodiment, WL1 or in general all WLs of NVM array 200 serve two functions. First, similar to WLs 106 in FIGS. 2A and 2B, WLs of NVM array 200 connects NVM cells 202 at their respective gates of the same row or column, depending on the arrangement of NVM array 200. WLs of NVM array 200 also function as a gate of each NVM cell 202 of the same row or column. For instance, WL1 functions as a gate to NVM cells C12, C11, C13, and C14, as best shown in FIG. 4B. In one embodiment, WLs of NVM array 200 may include one or more layer of polysilicon, aluminum, titanium, titanium-nitride, tungsten or compounds or alloys thereof. Adjacent NVM cells 202 that share a common BL, such as C12 and C13 sharing BL2, are coupled at their respective upper S/D regions 306 by BL connect 302 to BL2. BL connect 302 may include conductive material including but not limited to one or more layer of aluminum, titanium, titanium-nitride, tungsten or compounds or alloys thereof. As best shown in FIG. 5A, NVM cells 202 and BLs such as BL1, BL2, BL3 are electrically insulated from one another by one or more interlevel dielectric (ILD) layer 330 that includes non-conductive or dielectric material such as silicon oxide, silicon nitride, or silicon oxynitride. In one embodiment, all NVM cells 202 of NVM array 200 are arranged in one single layer, disposed vertically between BLs and SLs, and having memory film stack portion surrounded by corresponding WLs.

FIG. 5B is a representative block diagram illustrating a vertical cross-sectional view of NVM array 200 along cutting plane line CC-CC′ in FIG. 4B. As best shown in FIGS. 4B and 5B, NVM cells C12 and C11 are adjacent to one another, disposed along and over, and therefore share the common SL1. In one embodiment, SL1 functions as a source line connecting both NVM cells C12 and C11, as well as lower S/D regions 305 for both, respectively. As best shown in FIG. 5B, SL1 runs in a perpendicular direction (left and right) to WL1 (in and out).

FIG. 5C is a representative block diagram illustrating a horizontal cross-sectional view of NVM cell C12 along cutting plane line A-A′ in FIG. 5B. NVM cells 202, such as NVM cell C12 as shown, adopts a circular or oval cross-sectional shape. As best shown in FIG. 5C, vertical channel 304 is in the middle in which electric current/charges runs between upper and lower S/D regions 306 and 305. In one embodiment, vertical channel 304 may be formed with a single layer of doped or undoped semiconductor material, such as p-doped single crystal silicon, polysilicon, or other materials adopted for building channel of charge-trapping NVM transistors. In other embodiments, vertical channel 304 may adopt a macaroni channel configuration, including outer channel layer 304a and channel filler 304b. Outer channel layer 304a may include a single layer or more of doped semiconductor material, such as p-doped single crystal silicon, polysilicon, or other materials adopted for building channels of charge-trapping NVM transistors. Channel filler 304b may be formed by depositing a layer or more of dielectric material, such as silicon oxide or silicon oxynitride to fill the void. Vertical channel 304 is disposed adjacent to or surrounded by tunnel oxide layer 308. Tunnel oxide layer 308 is disposed adjacent to or surrounded by charge-trapping layer 310. Charge-trapping layer 310 is disposed adjacent to or surrounded by blocking dielectric layer 312. In one embodiment, tunnel oxide layer 308, charge-trapping layer 310, and blocking dielectric layer 312 form an oxide-nitride-oxide (ONO) stack, resembling the ONO stack in planar NVM transistor 108 shown in FIG. 2B. It will be the understanding that each of layers in the ONO stack may be single or multiple-layered. The ONO stack is disposed adjacent to or surrounded by WL1 that functions as the metal gate to NVM cell C12. In embodiments, WL1 may turn NVM cells, such as NVM cell C12, on or off in various operations (such as read, program, erase, etc.) by appropriate biasing practiced by one having ordinary skill in the art. In one embodiment, blocking dielectric layer 312 may also include hi-K dielectric layer 311, making NVM cell C12 a hi-K metal gate (HKMG) device. In another embodiment, instead of the ONO stack, the memory film stack may include one or more layers of ferroelectric film, such as hafnium dioxide (HfO₂). Optionally having one or more layer of dielectric or interfacial layer, such as silicon oxide or oxynitride, disposed between vertical channel 304 and the ferroelectric film (not shown in FIG. 5C).

FIG. 5D is a representative block diagram illustrating a vertical cross-sectional view of NVM array 200 along cutting plane line BB-BB′ in FIG. 4B. As best shown in FIG. 5D, BLs such as BL1, BL2, and BL3, are electrically and physically isolated from each other and from WLs, such as WL1, by ILD layer 330. In one embodiment, cutting plane line BB-BB′ does not intersect with any NVM cell 202. WL1 is also electrically and physically isolated from SL1, SL2, and substrate 318 by two dielectric layers 312 and 310. As best shown in FIG. 5B, WL1 runs in a perpendicular direction (left and right) to BLs and SLs (in and out).

FIG. 5E is a representative block diagram illustrating a vertical cross-sectional view of NVM array 200 along cutting plane line DD-DD′ in FIG. 4. As best shown in FIG. 5E, BL connector 302 that coupled NVM cells C12 and C13 to BL2 is electrically and physically isolated from WL1 by ILD layer 330. While running in the same direction (left and right), BLs and SLs (absent in this cross-sectional view) do not intersect in the same vertical plan.

Compared to conventional two-dimensional (2D) horizontal memory device, the channel of NVM device of the present embodiment, such as NVM cell 202, is substantially vertical. One advantage of vertical channel devices is that area scaling is decoupled from channel scaling, which maintains breakdown voltage while always degrades in horizontal device scaling. Another advantage is that vertical channels are separated from one another and sealed by SL, which largely eliminates transient program disturb that would have happened to adjacent horizontal devices. Yet another advantage is that gate all around features in the vertical channel device shield device channel and charge trapping layers from neighboring devices, and there is no adjacent WL disturb as for horizontal device. Yet another advantage is that vertical channel device sensing current is determined by the perimeter of the device channel, which gives more scaling margin compared to reducing device width in horizontal devices.

FIG. 6A illustrates a flow diagram depicting sequences of particular modules employed in the fabrication process 600 of a NVM array/device integrated with a logic MOS device, such as NVM device 100 in FIG. 1, in accordance with particular embodiments of the present invention. FIG. 7A-7P are representative diagrams illustrating a portion of NVM device 900 at various points during its manufacture according to the method of fabrication of FIG. 6A. In one embodiment, NVM device 900 may have similar configurations and structural features as NVM device 100 in FIG. 1, including a non-volatile memory or core region 700 and a periphery or logic region 800 fabricated in a single substrate 708. In embodiments, the logic region may further include LV, I/O, and H/V areas wherein MOS transistors having different operational voltages are disposed. In one embodiment, NVM device 900 is an n-type NVM device, such that NVM cells 750 are n-channel devices. It would be the understanding that fabrication process in this patent document may be modified to fabricate p-type NVM devices by adopting an opposite or different doping scheme, as practiced by one having ordinary skill in the art.

Referring to FIGS. 6A, 7A and 7B, the manufacturing process may begin with an optional pre-clean step of substrate 708 (step 602). FIG. 7B illustrates a representative top view of core region 700 in substrate 708, while FIG. 7A illustrates a representative vertical cross-sectional view along cutting plane A-A of substrate 708. In one embodiment, substrate 708 is divided into core region 700 wherein NVM elements (e.g. NVM cells/arrays) will be fabricated thereon and periphery region 800 wherein logic elements (e.g. logic MOSFETs, I/O MOSFETs, HV MOSFETs) will be fabricated thereon. Although only one of each region is shown in FIG. 7A, it will be the understanding that it is merely one example and multiple core and periphery regions may be present in one substrate 708. Core and periphery regions 700 and 800 may be formed immediately adjacent one another as shown in FIG. 7A, or may be disposed in other arrangements. A mask (not shown) is formed to protect periphery region 800 for doping and other processes performed in core region 700. In embodiments, the mask may be a hard mask or photoresist mask, or other techniques practice by in the art.

Referring to FIG. 7B, substrate 708 in core region 700 is divided into one or more isolation region(s) 704 and lower source/drain (S/D) region(s) 702. The substrate 708 may be a bulk substrate composed of any single crystal material suitable for semiconductor device fabrication, or may include a top epitaxial layer of a suitable material formed on a substrate. In one embodiment, suitable materials for substrate 708 include, but are not limited to, silicon, germanium, silicon-germanium or a Group III-V compound semiconductor material. As best shown in FIG. 7B, each region 702 and 704 resembles an elongated structure extending horizontally or in the same direction across substrate 708. Elongated structures of isolation region(s) 704 and lower source/drain region(s) 702 are disposed in alternate manner across substrate 708. As previously explained, lower S/D regions 702 may function as a source line connecting NVM cells 750 of the same column or row, depending on the orientation of NVM device 900. In one embodiment, NVM cells 750, as shown as footprints in FIG. 7B, would be fabricated within and overlying lower source/drain region(s) 702. Referring to FIGS. 6 and 7A, dopants 703 are implanted into substrate 708 to form lower S/D regions or junctions 702 (step 604). The dopants 703 implanted may be of any type and concentration, and may be implanted at any energy, including energies necessary to form heavily doped negative implant (N+ implant). Negative dopant implants 703 may include arsenic ions, phosphorus ions, etc. It is further appreciated that lower S/D regions 702 may be formed by depositing and patterning a mask layer (not shown), such as a photoresist layer or a hard mask above surface of substrate 708, and implanting an appropriate ion species at an appropriate energy to an appropriate concentration. P-type dopant implants, such as boron ions may be used in p-type NVM cells, as would be practiced by one having ordinary skill in the art. As best shown in FIG. 7B, footprints of would be fabricated NVM cells 750 are disposed within lower S/D region(s). In one embodiment, lower S/D regions may be formed to a depth of an approximate range of 100 Å to 7500 Å.

Referring to FIGS. 6A and 7B, isolation regions 704 are formed to separate each of lower S/D region 702 both physically and electrically (step 606). In embodiments, isolation regions may include a dielectric material, such as oxide or nitride, and may be formed by any conventional technique, including but not limited to shallow trench isolation (STI) or local oxidation of silicon (LOCOS). Optionally, chemical mechanical planarization (CMP) may be performed to produce a level substrate surface for subsequent process(es). In embodiments, isolation regions 704 may be formed before, after, or concurrently with lower S/D regions 702, to a depth of an approximate range of 500 Å to 8000 Å. Subsequently and optionally, pad oxide (not shown) may be formed to cover the entire surface of substrate 708, including lower S/D regions 702 and isolation regions 704. Pad oxide may be silicon dioxide (SiO₂) having a thickness of from about 10 nanometers (nm) to about 20 nm or other thicknesses and may be grown by a thermal oxidation process or in-situ steam generation (ISSG) process, or other oxidation or deposition processes known in the art. It will be the understanding that pad oxide may not be necessary, or formed in some embodiments.

Still referring to FIGS. 7A and 7B, the mask protecting periphery region 800 may be removed and wells and/or channels are formed, in step 608. In embodiments, dopants are then implanted into substrate 708 through pad oxide (if present) to form wells 707 in which the logic devices, such as LV MOS may be formed therein. Subsequently or simultaneously, channels 709 for some or all logic devices in periphery region 800 may also be formed by performing dopant(s) implant. It will be the understanding that multiple wells of different dimensions and configurations and channels may be formed in periphery region 800 at this stage or later stages.

Next, referring to FIGS. 6A and 7C, periphery gate stack is formed and patterned, in step 610. The formation of the periphery gate stack begins with forming gate oxide layer 902 over the entire surface of substrate 708, both in core region 700 and periphery region 800. In embodiments, gate oxide layer 902 may be formed by any suitable deposition methods known in the art, including but not limited to chemical vapor deposition (CVD), atomic layer deposition (ALD), molecular beam epitaxy (MBE), to an approximate thickness of 0.5 nm to 25 nm. In one embodiment, gate oxide layer 902 will eventually become the gate dielectric for MOSFET devices, such as LV FET formed in periphery region 800.

Subsequently, gate layer 904 that will eventually become a portion of the gates for the MOSFET devices is deposited overlying gate oxide layer 902. In one embodiment, gate layer 904 is made from heavily doped, such as N+ doped, silicon or polysilicon. Gate layer 904 may be formed by any suitable deposition process, such as low pressure chemical vapor deposition (LPCVD), CVD and ALD, or other deposition process(es) practiced in the art. Then, a layer of tungsten silicide (WSi) as MOS gate layer 906 is formed overlying gate layer 904. In one embodiment, MOS gate layer 906 is formed by a metal CVD process. In embodiments, MOS gate layer 906 may include different conductive materials including but are not limited to metal nitrides, metal carbides, metal silicides, hafnium, zirconium, titanium, tantalum, aluminum, ruthenium, tungsten, palladium, platinum, cobalt, and nickel, which are known in the art and may be adopted. In combination, gate layer 904 and MOS gate layer 906 will eventually form the gates for MOSFET devices in periphery region 800. Then, height-enhancing (HE) or capping film 908 is formed overlying MOS gate layer 906. One function of HE film 908 is to boost or compensate the total height of the periphery gate stack to match the height of NVM cells would be formed in core region 700. In one embodiment, the height of HE film 908 is adjusted such that the total height of periphery gate stack is around approximately 200 nm, or other height. HE film 908 may include silicon nitride that is formed by suitable deposition process, such as CVD and ALD, or other processes known and practiced in the art.

Next, still referring to FIGS. 6A and 7C, the periphery gate stack is removed from core region 700, in step 612. In one embodiment, a hard mask or photoresist mask is formed exposing core region 700. The periphery gate stack previously formed, including HE film 908, MOS gate layer 906, gate layer 904, and gate oxide layer 902, in core region 700 is removed, using suitable etching process(es), such as plasma etching, wet etching, or other etching methods known in the art.

Referring to FIG. 7D, in embodiments wherein multiple types of MOSFET devices, such as LV FET 850a, I/O FET 850b, and HV FET 850c in different areas within periphery region 800. In one embodiment, HV FET 850c may have the largest gate dielectric thickness and LV FET 850a the smallest, such that gate oxide layers 902a, 902b, 902c formed in their respective area is formed to different thicknesses. It will be the understanding that NVM device 900 shown in FIG. 7D is used as an example, and NVM device 900 may have one or more types of MOSFET devices and each type of MOSFET device may be disposed adjacent to one another or not. In embodiments, gate oxide layers 902a, 902b, 902c in different MOSFET areas may be formed concurrently, or individually. As best shown in FIG. 7D, despite difference in thicknesses of gate oxide layers 902a, 902b, 902c in different MOSFET areas, the overall height of periphery gate stack is consistent throughout periphery region 800.

Referring to FIGS. 6A, 7E, and 7F, isolation layers are formed overlying the substrate 708, in step 614. In one embodiment, isolation nitride layer 908′ may be formed by any suitable deposition methods known in the art, including but not limited to chemical vapor deposition (CVD), atomic layer deposition (ALD), molecular beam epitaxy (MBE), to an approximate thickness of 5 nm to 40 nm in core region 700 and add thickness to the previously formed HE film 908 in periphery region 800. Isolation nitride layer 908′ may include silicon nitride formed overlying lower S/D regions 702 and isolation regions 704 in substrate 708, or overlying pad oxide if present and isolate core region 700 from periphery region 800 physically. Next, isolation oxide layer 910 is formed overlying isolation nitride layer in core region 700 only to a thickness in an approximate range of 50 nm to 300 nm. Isolation oxide layer 700 may include silicon oxide or oxynitride formed by any suitable deposition methods known in the art, such as CVD, PVD, ALD, and MBE. Next, a CMP process may be performed in both regions for a level top surface. As best shown in FIG. 7F, isolation nitride layer 908′ and HE film 908 may protect the periphery gate stack in periphery region 800 during the subsequent steps of forming the NVM cells in core region 700, in step 616.

Referring to FIGS. 6A and 6B, NVM cells are fabricated in core region 700, in step 616, and in steps 650 to 658. As best shown in FIG. 7G, in core region 700, vertical openings 710, which are substantially perpendicular to the plane of substrate 708, may be formed in locations where vertical channels of each NVM cells 750 may be subsequently formed, in step 650. In one embodiment, there may be vertical openings 710 and each is formed within its corresponding lower S/D region 702 in substrate 708. It is the understanding that the vertical axis of vertical openings 710 may be disposed at a right angle (90°) or an approximate right angle to the top surface of substrate 708. As best shown in FIG. 7G, vertical openings 710 may be formed by etching isolation oxide layer 910 and isolation nitride layer 908′, and stopped at the top surface of lower S/D region 702, using suitable etching processes, such as plasma etching, wet etching, or other etching methods known in the art. In one embodiment, vertical openings 710 provide a space to fabricate NVM cells 750 therein in subsequent process steps. By configuring the depth of vertical openings 710 or the thickness of isolation layers 910 and 908′, channel length of NVM cell 750 may be controlled, and to match MOSFET device heights in periphery region 800 (not shown).

Next, referring to FIGS. 6B and 7H, vertical channel and gate dielectric layer or ON stack are formed within vertical openings 710 (step 652). In one embodiment, vertical channels may be formed after the ON stacks, in a channel last process flow as described in FIGS. 7H and 7I. In another embodiment, vertical channels may be formed before the ON stacks, in a channel first process flow (not shown). One having ordinary skill in the art would comprehend that, regardless of the sequence of vertical channel and ON stack formation, it would yield the final structure of NVM cells 750, as best shown in FIG. 7S.

It will be the understanding that, only two NVM cells 750 similar to C12 and C13 in FIG. 4B, that share a single word line (WL1) and bit line (BL2), and coupled with adjacent source lines (SL1 and SL2) are shown as examples of NVM devices fabricated by the process flow of the present disclosure. Other NVM cells 750 in the NVM device 900 may adopt similar process flow and be fabricated concurrently or subsequently. In one embodiment, a memory film stack in the form of ONO stack is used as an example of NVM devices fabricated by the process flow of the present disclosure. One having ordinary skill in the art would understand that NVM devices having other memory film stack, such as the ferroelectric film stack (with or without the interfacial layer), may be fabricated with the same process flow with slight adjustments.

### ON (Memory Film Stack) First/Channel Last Process Flow

Referring to FIG. 7H, charge-trapping layer 718 and tunnel oxide or dielectric layer 716 are formed within vertical opening 710. In various embodiments, charge-trapping layer 718 is a single layer and may include a layer of silicon nitride and/or silicon oxynitride formed on or overlying or in contact with side surface of vertical opening 710. The charge-trapping layer 718 may be formed by suitable conformal deposition process, such as CVD and ALD. In one embodiment, charge-trapping layer 718 may have a relatively uniform thickness of from about 30 Å to about 100 Å or other thicknesses. After the deposition process, charge-trapping layer 718 is a continuous layer, or coating the entire length of vertical opening 710, including the bottom (not shown in FIG. 7H). In one embodiment, charge-trapping layer 718 may trap charge carriers during operations of NVM cells 750. As explained in previous sections associated with FIG. 5A, charge-trapping layer 718 may include one or more spatially separated regions in which charge carriers are trapped, in order to retain more than one or more bit of binary data, or multiple level data. In other embodiments, charge-trapping layer 718 may include multiple layers of silicon oxynitride that have a stoichiometric ratio of oxygen, nitrogen and/or silicon that are different from one another. Next, tunnel dielectric layer 716 is formed in vertical opening 710. In one embodiment, tunnel dielectric layer 716 may be formed on or overlying or in contact with the charge-trapping layer 718 within vertical opening 710. For example, a layer of dielectric material may be deposited by CVD or ALD process conformally over charge-trapping layer 718, or thermally grown. In various embodiments, the layer of dielectric material may include, but not limited to silicon dioxide, silicon oxynitride, silicon nitride, aluminum oxide, hafnium oxide, zirconium oxide, hafnium silicate, zirconium silicate, hafnium oxynitride, hafnium zirconium oxide and lanthanum oxide. Generally, tunnel dielectric layer 716 has a relatively uniform thickness of from about 20 Å to about 70 Å or other thicknesses suitable to allow charge carriers to tunnel into the charge-trapping layer 718 under an applied control gate bias while maintaining a suitable barrier to leakage when the applied gate is unbiased.

In certain embodiments, tunnel dielectric layer 716 is silicon dioxide, silicon oxynitride, or a combination thereof and can be grown by a thermal oxidation process, using plasma or radical oxidation of a top portion of charge-trapping layer 718.

Next, the process of multi-layer punch or etch is performed. In one embodiment, the multi-layer punch may be performed to remove a portion of the ON stack disposed at the bottom of vertical opening 710. As best shown in FIG. 7H, an etching process is performed to remove tunnel dielectric 716 and charge-trapping 718 layers previously formed at the bottom of vertical opening 710. In one embodiment, plasma etch process is performed until the bottom of vertical opening 710 at least reaches or gouges into lower S/D region 702. Etchants 711 may include fluorine-based chemicals, such as CF₄, C₄F₆, CH₂F₂, NF₃, and O₂ and Ar, or others practiced in the art. In one embodiment, the multi-layer punch is performed until lower S/D region 702 is exposed.

Next, still referring to FIGS. 6B and 7I, vertical channels 720 are formed within and to fill out vertical openings 710. As an example and described earlier, NVM cells 750 are n-channel or n-type device. Therefore, vertical channels 720 include semiconductor material with p-type dopants, such as boron ions. In one embodiment, vertical channel 720 is formed at the bottom of vertical opening 710 and overlying lower S/D region 702. Vertical channel 720 may be composed of single crystal silicon or polysilicon, fabricated using selective epitaxial growth (SEG) techniques in which growth may occur on exposed silicon areas of substrate 708. Regions on which silicon growth is not desired may be masked by a dielectric film, typically silicon dioxide or silicon nitride. Silicon grown in the SEG process may be undoped. Subsequently, undoped vertical channel 720 may be implanted with p-type dopants using doping techniques practice in the art. Alternatively, SEG grown silicon may be doped. In some embodiments, silicon grown in vertical channel 720 may be positively doped, negatively doped, and the doping may be in-situ doping. Doping of vertical channel 720, if performed, may be carried out either during the SEG step or after. Since positively doped vertical channel 720 is in direct contact with heavily and negatively doped lower S/D region 702, n-type dopants in lower S/D region 702 may diffuse upwardly and create an intervening structure, lower S/D buffer 730, that is lightly doped with negative implants.

Next, still referring to FIGS. 6B and 7I, upper S/D regions or junctions of NVM cells are formed, in step 654. As best shown in FIG. 7I, vertical channel 720 is grown until it fills out vertical opening 710 and form a circular overhang such that tunnel dielectric 716 and charge-trapping 718 layers are protected and not exposed. In one embodiment, the circular overhang is not removed and a thin oxide layer 722 is formed over its surface by oxidation or deposition process(es) known and practiced in the art. Subsequently, the circular overhang is implanted heavily through thin oxide layer 722 with n-type dopants 724. The dopants 724 implanted may be of any type and concentration, and may be implanted at any energy, including energies necessary to form heavily doped negative implant (N+ implant). Negative dopant implants 724 may include arsenic ions, phosphorus ions. Consequently, the circular overhang is heavily doped to form upper S/D region or junction 726 for NVM cell 750.

Similarly, since the positively doped vertical channel 720 is in direct contact with heavily and negatively doped upper S/D region 726, n-type dopants in upper S/D region 726 may diffuse downwardly and create an intervening structure, upper S/D buffer 728, that is lightly doped with negative implants.

In one alternative embodiment, as best shown in FIG. 7J, the circular overhang created during the formation of vertical channel 720 is etched down with a portion of tunnel dielectric 716 and charge-trapping 718 layers that creates opening 729. In embodiments, suitable etching processes, such as plasma etching, wet etching, and others, may be adopted. As best shown in FIG. 7K, a layer of S/D silicon 726′ is formed to fill out opening 729. In embodiments, S/D silicon 726′ may be formed by any suitable deposition process, such as low pressure chemical vapor deposition (LPCVD), CVD and ALD, or other deposition process(es) practiced in the art. Subsequently, S/D silicon 726′ is implanted heavily with n-type dopants 724. The dopants 724 implanted may be of any type and concentration, and may be implanted at any energy, including energies necessary to form heavily doped negative implant (N+ implant). Negative dopant implants 724 may include arsenic ions, phosphorus ions. Alternatively, S/D silicon 726′ may also be formed using SEG grown silicon with in-situ doping of appropriate type(s). Consequently, the S/D silicon 726′ is heavily doped to form upper S/D region or junction 726 for NVM cell 750. Similarly, since the positively doped vertical channel 720 is in direct contact with heavily and negatively doped upper S/D region 726, n-type dopants in upper S/D region 726 may diffuse downwardly and create an intervening structure, upper S/D buffer 728, that is lightly doped with negative implants.

### Channel First/ON (Memory Film Stack) Last Process Flow

In another embodiment, a channel first/ON last process flow begins with silicon growth in vertical openings 710. In one embodiment, vertical channel 720 is formed within and to fill out vertical openings 710. As an example and described earlier, NVM cells 750 are n-channel or n-type device. Therefore, vertical channels 720 include semiconductor material implanted with p-type dopants, such as boron ions. In one embodiment, vertical channel 720 is formed at the bottom of vertical opening 710 and overlying lower S/D region 702. Vertical channel 720 may be composed of single crystal silicon or polysilicon, fabricated using selective epitaxial growth (SEG) techniques in which growth may occur on exposed silicon areas of substrate 708. Regions on which silicon growth is not desired may be masked by a dielectric film, typically silicon dioxide or silicon nitride. In one embodiment, SEG grown silicon is doped. Silicon grown in vertical channel 720 may be positively doped, negatively doped, and the doping may be in-situ doping. Doping of vertical channel 720, if performed, may be carried out either during the SEG step or after. Since positively doped vertical channel 720 is in direct contact with heavily and negatively doped lower S/D region 702, n-type dopants in lower S/D region 702 may diffuse upwardly and create an intervening structure, lower S/D buffer 730, that is lightly doped with negative implants. In one embodiment, vertical channel 720 is grown until it forms a circular overhang over vertical opening 710. Next, circular overhang of vertical channel 720 is etched back. The etching process may be plasma etch or CMP. After the circular overhang is removed, isolation oxide layer 910 is removed. Isolation oxide layer 910 may be removed by plasma etching, wet etching, or other etching process(es) practiced in the art. The etching process stop at isolation nitride layer 908′ and vertical channel 720.

Next, tunnel dielectric layer and charge-trapping layer are formed overlying substrate 708. In one embodiment, tunnel dielectric layer 716 is formed conformally overlying isolation nitride layer 908′ and exposed surface of vertical channel 720. For example, a layer of dielectric material may be thermally grown, or deposited by CVD or ALD process conformally over the entire substrate 708. In various embodiments, the layer of dielectric material may include, but not limited to silicon dioxide, silicon oxynitride, silicon nitride, aluminum oxide, hafnium oxide, zirconium oxide, hafnium silicate, zirconium silicate, hafnium oxynitride, hafnium zirconium oxide and lanthanum oxide. Generally, tunnel dielectric layer 716 has a relatively uniform thickness of from about 20 Å to about 70 Å or other thicknesses suitable to allow charge carriers to tunnel into the charge-trapping layer 718 under an applied control gate bias while maintaining a suitable barrier to leakage when the applied gate is unbiased. Next, in various embodiments, charge-trapping layer 718 is a single layer and may include a layer of silicon nitride and/or silicon oxynitride formed on or overlying or in contact with tunnel dielectric layer 716. The charge-trapping layer 718 may be formed by suitable conformal deposition process, such as CVD and ALD. In one embodiment, charge-trapping layer 718 may have a relatively uniform thickness of from about 30 Å to about 100 Å or other thicknesses. After the deposition process, charge-trapping layer 718 is a continuous layer overlying tunnel dielectric layer 716. In one embodiment, charge-trapping layer 718 may trap charge carriers during operations of NVM cell 750. As explained in previous sections associated with FIG. 5A, charge-trapping layer 718 may include one or more spatially separated regions in which charge carriers are trapped, in order to retain more than one or more bit of binary data, or multiple level data. In other embodiments, charge-trapping layer 718 may include multiple layers of silicon oxynitride that have a stoichiometric ratio of oxygen, nitrogen and/or silicon that are different from one another. Next, a second isolation oxide layer may be similar to isolation oxide layer 910, is formed overlying all features on or within substrate 708. Second isolation oxide layer 912 may include silicon oxide and formed by deposition processes such as CVD and ALD. Next, second isolation oxide layer 912 is subsequently planarized using CMP or similar process(es) until at least charge-trapping layer 718 overlying vertical channel 720 is exposed.

In one embodiment, the process flow of channel first/ON last embodiment may also advance to step 654 of FIG. 6B, wherein upper S/D regions may be formed. As previously explained, a portion of vertical channel 720, tunnel dielectric 716 and charge-trapping 718 layers are etched down that creates opening 729. As best shown in FIG. 7J, a layer of S/D silicon 726′ is formed to fill out opening 729. In embodiments, S/D silicon 726′ may be formed by any suitable deposition process, such as low pressure chemical vapor deposition (LPCVD), CVD and ALD, or other deposition process(es) practiced in the art. Subsequently, S/D silicon 726′ is implanted heavily with n-type dopants 724. The dopants 724 implanted may be of any type and concentration, and may be implanted at any energy, including energies necessary to form heavily doped negative implant (N+ implant). Negative dopant implants 724 may include arsenic ions, phosphorus ions. Alternatively, S/D silicon 726′ may also be formed using SEG grown silicon with in-situ doping of appropriate type(s). Consequently, the S/D silicon 726′ is heavily doped to form upper S/D region 726 for NVM cell 750. Similarly, since the positively doped vertical channel 720 is in direct contact with heavily and negatively doped upper S/D region 726′, n-type dopants in upper S/D region 726 may diffuse downwardly and create an intervening structure, upper S/D buffer 728, that is lightly doped with negative implants. It will be the understanding that both channel first/ON last or ON first/channel last process flows would yield a similar interim device structure, as best shown in FIG. 7K.

Next, referring to FIGS. 6B and 7L, blocking dielectric layer of NVM cells are formed to complete the ONO stack of NVM cells, in step 656. Although NVM cells 750 having a flat upper S/D region 726 (no overhang vertical channel as in FIG. 7K) is shown as an example, it will be the understanding that the following process flow can be adopted by NVM cells 750 having a circular upper S/D region 726, as best shown in FIG. 7I. In one embodiment, isolation oxide layer 910 is removed by suitable etching process, such as plasma etch or wet etch. A conformal layer of blocking dielectric layer 732, to a uniform thickness in an approximate range of 30 Å to 100 Å, is formed overlying NVM cells 750 and the rest of substrate 708, including both core and periphery regions 700 and 800. In embodiments, blocking dielectric layer 732 may include any material and have any thickness suitable to insulate charge-trapping layer 718 from the to be formed gate of NVM cell 750. In some embodiments, blocking dielectric layer 732 may include silicon dioxide, silicon oxy-nitride, or a combination thereof and may be grown by a thermal oxidation process, using ISSG or radical oxidation, or conventional deposition processes, such as CVD and ALD, known in the art. In embodiments, there may be a high dielectric constant or high-K dielectric material or layer formed or deposited on or over blocking dielectric layer 732. The high-K dielectric layer (not shown) may include, but is not limited to, aluminum oxide, hafnium oxide, zirconium oxide, hafnium silicate, hafnium oxy-nitride, hafnium zirconium oxide and lanthanum oxide deposited to a physical thickness between about 0.5 nm and about 5nm or other thicknesses by, for example, atomic layer deposition (ALD), physical vapor deposition (PVD), a chemical vapor deposition (CVD), a low pressure CVD (LPCVD) or a plasma enhanced CVD (PECVD) process. Optionally, NVM device 700 will then undergo annealing as practiced by one having ordinary skill in the art. Next, the process flow will proceed to step 618 back in FIG. 6A.

Next, referring to FIGS. 6A and 7M, metal gate/word line is formed around NVM cells, in step 618. FIG. 7M is a representative block diagram illustrating a vertical cross-sectional view of NVM device or core region 700 along the cutting plane A-A of FIG. 7B, at this point of fabrication process after metal gate layer 734 is formed. In one embodiment, a layer of conductive material, such as tungsten (W), is formed using a metal CVD process overlying and encapsulating NVM cells 750 and cover the entire substrate 708, including periphery region 800. In embodiments, metal gate layer 734 may include different conductive materials including but are not limited to metal nitrides, metal carbides, metal silicides, hafnium, zirconium, titanium, tantalum, aluminum, ruthenium, tungsten, palladium, platinum, cobalt, and nickel, which are known in the art and may be adopted. As best shown in FIG. 7M, two NVM cells 750 are coupled to the same word line and respectively to adjacent source lines (similar to C12 and C13 of FIG. 4B). In one embodiment, metal gate layer 734 functions both as metal gate to provide biasing voltages to individual NVM cells 750 and a word line coupling multiple NVM cells 750 in one direction that is substantially perpendicular to SLs and BLs.

Next, as best shown in FIG. 7N, metal gate layer 734 is planarized and etched back to below the top level of the memory film or ONO stack of NVM cells 750 and to laterally encapsulate all NVM cells 750 of the same WL within a predetermined WL width. In one embodiment, metal gate layer 734 is completely removed in periphery region 800, either during the etching down process or separately.

Referring still to FIG. 7N, oxide pad layer 910 is formed over metal gate layer 734 in core region 700 and blocking dielectric 732 in periphery region 800. Oxide pad layer 910 may be formed by deposition process(es) such as ALD, CVD and/or oxidation process(es) such as wet oxidation, plasma oxidation known and practiced in the art.

Next, referring to FIGS. 6A and 7O, periphery gate stack is patterned, in step 620. As best shown in FIG. 7O, hard mask 912 is formed overlying the entirety of both core and periphery regions 700 and 800. Hard mask 912, that may include silicon nitride or oxynitride, is then patterned using conventional topographical techniques to expose source and drain regions of MOSFET or logic devices, such as LV FET 850a, that would be formed in periphery region 800. Although only one and one type of MOSFET device is shown in FIG. 7O, it would be the understanding that one or multiple of MOSFET devices of the same type or different types may be patterned or formed concurrently or individually. As best shown in FIG. 7O, the exposed portions of periphery gate stack are removed by one or multiple etch process(es), such as plasma etch, wet etch, dry etch, until gate dielectric layer 902 or substrate 708 is exposed. Subsequently, LDD implants may be performed in or around source and/or drain regions of LV FET 850a and/or other MOSFET devices formed concurrently, in step 622.

Next, referring to FIGS. 6A and 7P, gate spacers are formed in MOSFET devices, in step 622. Gate spacer layers, such as silicon oxide, oxynitride, nitride or combinations thereof are deposited and etched to form gate spacers 914 on the sides of LV FET 850a. Dopants 922 of the appropriate types will then be implanted in substrate 708 through patterned hard mask 912 to form source/drain regions 920 for each MOSFET device, such as LV FET 850a. After all source/drain regions 920 are formed, hard mask 912 is removed by conventional method(s).

Referring to FIGS. 6A and 7Q, gate and local interconnect (LI) contacts are formed in periphery region 800, in step 624. In one embodiment, isolation oxide layer 910′ is deposited between MOSFET devices, such as LV FET 850a, at least in periphery region 800. Then isolation oxide layer 910′ is planarized using CMP process. A photoresist mask or hard mask (not shown) is then formed and patterned to expose periphery contacts to be formed.

Then, the exposed isolation oxide layer 910′ is etched out to form periphery contact holes using conventional etching techniques, such as plasma etching. In one embodiment, the mask is then removed and the periphery contact holes are filled with tungsten or other metal layers to form S/D or LI contacts 916 and gate contacts 918. In one embodiment, S/D contacts 916 are coupled with S/D regions 920 while gate contacts 918 are coupled with metal gate layer 906 of MOSFET devices, such as LV FETs 850a. Then, optionally, the entire top surfaces of isolation oxide layer 910′, S/D contacts 916, and gate contacts 918 are planarized using CMP process. In some embodiments, SL contacts (not shown in FIG. 7Q) in core region 700, such as SL contacts 1008 as best shown in FIG. 4A, may be formed simultaneously with S/D contacts 916 in periphery region 800, using similar process steps as discussed above.

Referring to FIGS. 6A and 7R, upper S/D region contacts or BL connects are formed to couple NVM cells of the same BL, in step 626. FIG. 7R illustrating a vertical cross-sectional view along cutting plane A-A of FIG. 7B, showing two adjacent NMM cells along or coupled to adjacent SLs (e.g. SL1 and SL2 in FIG. 4) and the same WL (e.g. WL1). Referring to FIGS. 6A and 7R, oxide layer(s) is deposited over the entire substrate 708 such that isolation oxide layer 910″ thickness increases. Next, a photoresist or hard mask (not shown) is formed and patterned at least in the core region 700 exposing at least a portion of the top of NVM cells 750. In one embodiment, S/D contact openings are created in isolation oxide layer 910″ by an etching process, such as plasma etching and wet etching. As best shown in FIG. 7R, the S/D contact openings are formed overlying NVM cells 750. The etch process may include one or more separate steps, including one or multiple etching with different etchants, being configured to expose the conducting or conductive upper S/D regions 726 of NVM cells 750. Then, the photoresist mask or hard mask is removed. The upper S/D contact openings are filled with metal layers such as tungsten to form upper S/D region contact or BL connect 922. In some embodiments, upper S/D region contact or BL connect 922′ may be elongated horizontally (as shown in dotted line) and connecting two adjacent NVM cells 750 coupled to the same bit line, such as C12 and C13 to BL2, as best shown in FIG. 4B. Horizontal BL connect 922′ may take similar structural shape as BL connect 302 as best shown in FIG. 5A. Once upper S/D region contact 922 is formed, optional CMP process or etch back process is performed over the top surfaces; and oxide layer(s) is deposited overlying the entire substrate to increase the thickness of isolation oxide layer 910″ again until the newly formed upper BL connect 922 is completely covered and encapsulated. In some embodiments, vias 921 overlying S/D contacts 916 and gate contacts 918 in periphery region 800 and/or overlying SL contact in core region 700 are formed concurrently and with similar process steps as BL connect 922. In other embodiments, BL connect 922 is formed first and followed by a CMP process. Then vias, such as vias 921 in periphery region and/or vias overlying BL connect 922 (not shown) may be formed concurrently. In embodiments, vias overlying BL connect 922 may not be formed at all.

Still referring to FIG. 7R, another photoresist mask or hard mask (not shown) is formed and patterned to expose the newly formed BL connects 922 or 922′ or vias overlying BL connects 922 or 922′ (if present) in core region 700 and vias 921 in periphery region 800. Next, an etch process, such as plasma etch, is performed to create openings in isolation oxide layer 910′ exposing BL connects 922 or 922′ or vias in core region and vias 921 in periphery region 800. The mask is then removed. In one embodiment, all the openings just created are filled by a layer(s) of conductive material, such as copper, to form BLs 924 in core region 700, S/D connect 920 and gate connect 922 in periphery region 800. BLs 924, S/D connect 920, and gate connect 923 may be formed by a metal CVD process, followed by an etch back or CMP process to a planarized top surface. Other combinations using different conductive materials may include but are not limited to metal nitrides, metal carbides, metal silicides, hafnium, zirconium, titanium, tantalum, aluminum, ruthenium, tungsten, palladium, platinum, cobalt, and nickel, which are known in the art and may be adopted. In embodiments, BLs 924 may be the actual bit lines of core region 700 connecting multiple NVM cells 750 in one direction. Alternatively, BLs 924 may be a connecting structure coupling NVM cells 750 via BL connects 922 or 922′ to the actual bit lines. In those situations, an additional step to form BL pattern, similar to BL pattern in FIG. 4A will be performed afterwards.

Referring to FIGS. 6A and 7S, NVM device 900, including NVM cells or array(s) in the core region and MOSFET devices in the periphery region, is substantially completed. Finally, the standard or baseline CMOS process flow is continued to substantially complete the back end device fabrication (step 628). As best shown in FIG. 7S, one or multiple NVM cells 750 may be formed along and overlying lower S/D regions (also as SLs) 702. Upper S/D regions 726 of NVM cells 750 are also coupled to BLs 924 formed above through BL connects 922 or vias (not shown). Similar to NVM device 100 as best shown in FIG. 1, NVM device 900 may include periphery region 800 in which one or multiple types of MOSFETs or logic devices may be formed in different areas. As an example and best shown in FIG. 7S, there may be LV FETs 850a, I/O FETs 850b, and HV FETs 850c each formed in their respective area. In one embodiment, all MOSFET devices may have similar structural features except for the thickness of its gate dielectric. LV gate dielectric layer 902a is thinner than I/O gate dielectric layer 902b, and HV gate dielectric layer 902c is the thickest among them. As previously illustrated and explained in FIG. 7D and its corresponding description, gate dielectric layer 902a-c of different thicknesses may be formed concurrently in different areas or individually. In embodiments, gate layer 904, metal gate layer 906, and/or HE film 908 formed overlying gate dielectric 902a-c may offset the difference in gate dielectric thicknesses. As a result, periphery stack of LV FETs 850a, I/O FETs 850b, and HV FETs 850c may have substantially the same thickness. Also, as previously explained, HE film 908 is used to control the channel 720 length (or height) of NVM cells 750 in core regions 700, overall height H of NVM cells 750 in core region 700 is therefore substantially the same as MOSFET devices 850a-c in periphery region 800. It will be the understanding that only one or two NVM cells and/or logic devices of NVM device 900 are shown in each region or area in FIG. 7S, it should not be construed as limitations. In embodiments, multiple NVM cells 750, LV FETs 850a, I/O FETs 850b, and HV FETs 850c may be formed, using the process flow as described in FIG. 6A-6B and 7A-7S, with or without slight adaptation known in the art, simultaneously or individually. One having ordinary skill in the art would also appreciate that in some NVM devices 900, one or more types of logic devices may be missing and different types of logic devices may be formed within one area. Multiple core and periphery regions 700 and 800 may exist in a single substrate, formed adjacent or not to or overlapping one another without violation of the principle of this disclosure.

Thus, embodiments of non-volatile memory devices having vertical channels and integration methods to CMOS process flow have been described. Although the present disclosure has been described with reference to specific exemplary embodiments, it will be evident that various modifications and changes may be made to these embodiments without departing from the broader spirit and scope of the disclosure. Accordingly, the specification and drawings are to be regarded in an illustrative rather than a restrictive sense.

The Abstract of the Disclosure is provided to comply with 37 C.F.R. § 1.72(b), requiring an abstract that will allow the reader to quickly ascertain the nature of one or more embodiments of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

Reference in the description to one embodiment or an embodiment means that a particular feature, structure, or characteristic described in connection with the embodiment is included in at least one embodiment of the circuit or method. The appearances of the phrase one embodiment in various places in the specification do not necessarily all refer to the same embodiment.

What is claimed is:

1. A semiconductor device, comprising:
a first region including at least one non-volatile memory (NVM) transistor formed over a substrate, each NVM transistor including:
a lower source/drain (S/D) junction and an upper S/D junction;
a vertical channel disposed between the upper and lower S/D junctions;
a cylindrical memory film stack surrounding the vertical channel; and
a gate layer disposed around the memory film stack; and
a second region including at least one logic transistor, each logic transistor including:
a gate dielectric layer overlying a horizontal channel;
a gate layer; and
a height-enhancement (HE) layer;
wherein the at least one NVM transistor in the first region and the at least one logic transistor in the second region have substantially a same device height.

2. The semiconductor device of claim 1, wherein:
the at least one logic transistor includes a low voltage (LV) transistor and a high voltage (HV) transistor, wherein the LV transistor includes a thinner gate dielectric layer than the HV transistor.

3. The semiconductor device of claim 1, wherein the gate layers of the at least one logic transistor are multi-layered and each comprises a metal gate layer overlying a doped silicon gate layer.

4. The semiconductor device of claim 1, wherein the first region further comprises:
a word line (WL) extending and coupling to the gate layers of the at least one NVM transistors in a first direction, wherein the gate layers of the at least one NVM transistors in the first direction form a portion of the WL.

5. The semiconductor device of claim 4, wherein the first region further comprises:
a source line (SL) extending and coupling to lower S/D junctions of at least one NVM transistors in a second direction, wherein the lower S/D junctions of the at least one NVM transistors in the second direction form a portion of the SL; and
a bit line (BL) extending and coupling to upper S/D junctions of at least one NVM transistors in the second direction, wherein the first and second directions are substantially perpendicular to one another.

6. The semiconductor device of claim 1, wherein the cylindrical memory film stack includes an oxide-nitride-oxide (ONO) stack including a charge-trapping layer disposed uprightly from a top surface of the substrate.

7. The semiconductor device of claim 1, wherein the HE film includes silicon nitride and is configured to:
protect the gate layer and the gate dielectric layer in the second region while the at least one NVM transistor is being formed in the first region; and
control channel length of the vertical channel of the at least one NVM transistor.

8. The semiconductor device of claim 1, wherein the lower S/D junction of the at least one NVM transistor and the horizontal channel of the at least one logic transistor are formed at least partially buried within the substrate.

9. The semiconductor device of claim 1, wherein the vertical channel has a circular cross-section and includes doped silicon of a positive type, and wherein the lower and upper S/D junctions include doped silicon of a negative type.

10. The semiconductor device of claim 9, wherein the vertical channel further comprises a channel filler including a dielectric layer surrounded by an outer channel shell including doped silicon of a positive type.

11. The semiconductor device of claim 6, wherein the charge-trapping layer is configured to retain electrical charges in more than one physically and spatially separated regions, and wherein the at least one NVM transistor is configured to store more than one bit of binary values.

12. The semiconductor device of claim 5, wherein the BL is coupled to the upper S/D junction of the NVM transistor via a BL connect, wherein the BL connect couples two neighboring NVM transistors to the BL.

13. The semiconductor device of claim 12, wherein the two neighboring NVM transistors are respectively coupled to two neighboring SLs, wherein the two neighboring SLs are electrically insulated from one another.

14. The semiconductor device of claim 1, wherein the semiconductor device is a bi-directional transistor device, and wherein the lower and upper S/D junctions are configured to function as both a source or a drain of the bi-directional transistor device.

15. The semiconductor device of claim 5, wherein the ONO stack is surrounded by a high-K dielectric layer and the gate layer includes a layer of tungsten, making the at least one NVM device a high-K metal gate device.

16. The semiconductor device of claim 5, wherein the at least one NVM transistor is arranged in one single layer and vertically disposed between the BLs and SLs.

17. An embedded semiconductor device, comprising:
a non-volatile memory (NVM) array disposed in a core region of a substrate, including:
a plurality of source lines (SLs) extending in a first direction, wherein adjacent SLs are insulated by shallow trench isolations (STIs);
NVM transistors formed overlying the plurality of SLs, each NVM transistor comprising a lower source/drain (S/D) junction, a vertical channel surrounded by a memory film stack and a metal gate layer, and an upper S/D junction overlying the vertical channel;
a plurality of word lines (WLs) coupling to the metal gate layers of the NVM transistors and extending in a second direction; and
a plurality of bit lines (BLs) overlying the upper S/D junctions and the metal gates of the NVM transistors, wherein the BLs are coupled to the upper S/D junctions of at least one NVM transistors and extend in the first direction and
at least one logic transistor disposed in a periphery region of the substrate, each logic transistor including a gate dielectric layer overlying a horizontal channel, a gate layer, and a height-enhancement (HE) layer.

18. The embedded semiconductor device of claim 17, wherein the second direction is substantially perpendicular to the first direction.

19. The embedded semiconductor device of claim 17, wherein the NVM transistors in the core region and the at least one logic transistor in the periphery region have substantially a same device height and arranged in one single layer and vertically disposed between the BLs and SLs.

20. A semiconductor device, comprising:
a plurality of non-volatile memory (NVM) transistors arranged in rows and columns formed in a substrate, wherein each NVM transistor comprises a lower source/drain (S/D) junction, a vertical channel surrounded by a memory film stack and a metal gate layer, and an upper S/D junction overlying the vertical channel;
a plurality of logic transistors formed in the substrate, each logic transistor including a gate dielectric layer overlying a horizontal channel, a gate layer, and a height-enhancement (HE) layer;
a plurality of word lines (WLs), each coupling NVM transistors of a same row, wherein metal gate layers of the NVM transistors of the row form a portion of the WLs;
a plurality of source lines (SLs), each coupling NVM transistors of two adjacent columns, wherein lower S/D junction of the NVM transistors of the two adjacent columns form a portion of the SLs; and
a plurality of bit lines (BLs), each coupling NVM transistors of at least one column via a plurality of BL connects.

21. The semiconductor device of claim 20, wherein the plurality of NVM transistors are formed overlying the plurality of SLs formed at least partly within the substrate, the plurality of SLs and BLs propagate in a same direction, and the plurality of WLs and BLs propagate in a perpendicular direction.

22. The semiconductor device of claim 20, wherein the plurality of NVM transistors and the plurality of logic transistors have substantially a same device height and arranged in one single layer disposed vertically between BLs and SLs.
